(19) United States
(12) Patent Application Publication
(10) Pub. No.: US 2016/0013207 A1
(43) Pub. Date: Jan. 14, 2016

(54) SEMICONDUCTOR DEVICE AND MANUFACTURING METHOD FOR THE SAME

(71) Applicant: Renesas Electronics Corporation, Kawasaki-shi (JP)

(72) Inventor: Hideki MAKIYAMA, Kanagawa (JP)

(73) Assignee: RENESAS ELECTRONICS CORPORATION

(21) Appl. No.: 14/794,105

(22) Filed: Jul. 8, 2015

(30) Foreign Application Priority Data
Jul. 8, 2014 (JP) 2014-140183

(51) Int. Cl. H01L 27/12; H01L 29/423; H01L 21/84

(52) U.S. Cl. CPC H01L 27/1203; H01L 21/84; H01L 29/42364; H01L 29/42376

(57) ABSTRACT

A semiconductor device including an SOI substrate reduces a gate leak current of an anti-antenna-effect dummy fill-cell and suppresses an antenna effect. The thickness of a gate insulating film of the anti-antenna-effect dummy fill-cell is determined to be large than that of a gate insulating film of an SOI transistor. This reduces the gate leak current of the anti-antenna-effect dummy fill-cell. The gate area (gate length×gate width) of the anti-antenna-effect dummy fill-cell is determined to be large than that (gate length×gate width) of the SOI transistor. This makes the gate capacity of the anti-antenna-effect dummy fill-cell almost equal to that of SOI transistor, thereby suppressing the antenna effect.

### CROSS-REFERENCE TO RELATED APPLICATION

The present application claims priority from Japanese Patent Application No. 2014-140183 filed on Jul. 8, 2014, the content of which is hereby incorporated by reference into this application.

### TECHNICAL FIELD OF THE INVENTION

The present invention relates to a semiconductor device and a manufacturing technique for the same that can be used preferably as, for example, a semiconductor device including an SOI (Silicon on Insulator) substrate and a manufacturing method for the same.

### BACKGROUND OF THE INVENTION

Japanese Laid-Open Patent Publication No. 2003-133559 (Patent Document 1) describes a technique according to which a first interconnect layer has at least one interconnect connected directly to an impurity diffusion region or connected to the same via an interconnect of an interconnect layer disposed below the first interconnect layer and a first ratio between the area of at least one interconnect and the area of the impurity diffusion region is determined to be equal to or smaller than a given value.

Japanese Laid-Open Patent Publication No. 2001-237322 (Patent Document 2) describes a technique according to which a fill-cell having an antistatic protective circuit is disposed in a gap between cells by an automatic arranging/wiring method, an antenna effect caused by a charged interconnect is verified using an EDA tool, and an interconnect requiring an antenna effect preventing measure is connected to the protective circuit of the fill-cell.

Japanese Laid-Open Patent Publication No. 2000-188338 (Patent Document 3) describes a technique according to which a gate insulating film of one MISFET is made of a material with a dielectric constant higher than that of a material making up a gate insulating film of a different MISFET and the electrical film thickness of the gate insulating film of the one MISFET is made smaller than that of the gate insulating film of the different MISFET.

### SUMMARY OF THE INVENTION

In a semiconductor device including an SOI substrate that performs substrate bias control, a gate electrode of a field-effect transistor (hereinafter “SOI transistor”) formed in a circuit cell portion is electrically connected to a gate electrode of a dummy fill-cell (hereinafter “anti-antenna-effect dummy fill-cell”) formed in a dummy fill-cell portion disposed in a space between circuit cell portions, via an interconnect. This structure disperses charged particles (plasma) accumulated on an interconnect, etc., thereby suppresses an antenna effect on a gate insulating film of the SOI transistor. The structure, however, poses a problem that a gate leak current is generated at the anti-antenna-effect dummy fill-cell, leading to an increase in an active current at the SOI transistor.

The other problems and novel characteristics of the present invention will be apparent from the description of the present specification and the accompanying drawings.

According to one embodiment, in a semiconductor device in which a gate electrode of an SOI transistor formed in a circuit cell portion is electrically connected to a gate electrode of an anti-antenna-effect dummy fill-cell formed in a dummy fill-cell portion via an interconnect, the thickness of a gate insulating film of the anti-antenna-effect dummy fill-cell is made larger than that of a gate insulating film of the SOI transistor. In addition, the gate area (gate length×gate width) of the anti-antenna-effect dummy fill-cell is made larger than that (gate length×gate width) of the SOI transistor, or a high dielectric constant film is used as the gate insulating film of the anti-antenna-effect dummy fill-cell. This makes the gate capacity of the anti-antenna-effect dummy fill-cell equal to that of the SOI transistor.

According to one embodiment, a semiconductor device including an SOI substrate reduces a gate leak current of an anti-antenna-effect dummy fill-cell and suppresses an antenna effect.

### BRIEF DESCRIPTIONS OF THE DRAWINGS

FIG. 1 is a plan view of main parts of a semiconductor device according to a first embodiment;

FIG. 2 is a cross-sectional view of main parts of a semiconductor device according to the first embodiment;

FIG. 3 is a graph showing an example of the relationship between the leak currents (Jg×Area) of an MIS transistor having a thick-film gate insulating film and an MIS transistor having a thin-film gate insulating film, the leak currents flowing from respective gates to sources/drains of both MIS transistors, and the gate capacities (Cg×Area) of both MIS transistors, according to the first embodiment;

FIG. 4 is a schematic plan view of an example of the dimensions of an SOI transistor and an anti-antenna-effect dummy fill-cell according to the first embodiment;

FIG. 5 is a plan view of main parts of a semiconductor device including a conventional anti-antenna-effect dummy fill-cell examined by the inventors;

FIG. 6 is a cross-sectional view of main parts of a semiconductor device including a protective diode examined by the inventors;

FIG. 7 is a cross-sectional view of main parts showing a manufacturing process for the semiconductor device according to the first embodiment;

FIG. 8 is a cross-sectional view of main parts of a semiconductor device during a manufacturing process following FIG. 7;

FIG. 9 is a cross-sectional view of main parts of a semiconductor device during a manufacturing process following FIG. 8;

FIG. 10 is a cross-sectional view of main parts of a semiconductor device during a manufacturing process following FIG. 9;

FIG. 11 is a cross-sectional view of main parts of a semiconductor device during a manufacturing process following FIG. 10;

FIG. 12 is a cross-sectional view of main parts of a semiconductor device during a manufacturing process following FIG. 11;

FIG. 13 is a cross-sectional view of main parts of a semiconductor device during a manufacturing process following FIG. 12;

FIG. 14 is a cross-sectional view of main parts of a semiconductor device during a manufacturing process following FIG. 13;

FIG. 15 is a cross-sectional view of main parts of a semiconductor device during a manufacturing process following FIG. 14;

FIG. 16 is a cross-sectional view of main parts of a semiconductor device during a manufacturing process following FIG. 15;

FIG. 17 is a cross-sectional view of main parts of a semiconductor device during a manufacturing process following FIG. 16;

FIG. 18 is a cross-sectional view of main parts of a semiconductor device during a manufacturing process following FIG. 17;

FIG. 19 is a cross-sectional view of main parts of a semiconductor device during a manufacturing process following FIG. 18;

FIG. 20 is a cross-sectional view of main parts of a semiconductor device during a manufacturing process following FIG. 19;

FIG. 21 is a cross-sectional view of main parts of a semiconductor device during a manufacturing process following FIG. 20;

FIG. 22 is a cross-sectional view of main parts of a semiconductor device during a manufacturing process following FIG. 21;

FIG. 23 is a cross-sectional view of main parts of a semiconductor device during a manufacturing process following FIG. 22;

FIG. 24 is a cross-sectional view of main parts of a semiconductor device during a manufacturing process following FIG. 23;

FIG. 25 is a cross-sectional view of main parts of a semiconductor device during a manufacturing process following FIG. 24; and

FIG. 26 is a cross-sectional view of main parts of a semiconductor device according to a second embodiment.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Further, in the embodiments described below, when referring to the number of elements (including number of pieces, values, amount, range, and the like), the number of the elements is not limited to a specific number unless otherwise stated or except the case where the number is apparently limited to a specific number in principle.

Further, in the embodiments described below, it goes without saying that the components (including element steps) are not always indispensable unless otherwise stated or except the case where the components are apparently indispensable in principle.

It is also obvious that expressions “composed of A”, “made up of A”, “having A”, and “including A” do not exclude elements other than an element A, except a case where these expressions are defined as expressions that refer exclusively to the sole element A. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Further, in the following embodiments, a MISFET (Metal Insulator Semiconductor Field Effect Transistor) is abbreviated as a MIS transistor. Also, in some drawings used in the embodiments described below, hatching is used even in a plan view so as to make the drawings easy to see. Further, components having the same function are denoted by the same reference symbols in principle throughout all drawings for describing the embodiments described below, and the repetitive description thereof is omitted. Hereinafter, the embodiments of the present invention will be explained in detail based on the drawings.

### First Embodiment

A semiconductor device including an SOI substrate has a problem that for example, a gate insulating film of an SOI transistor formed in a circuit cell portion is damaged by charged particles accumulated on an interconnect due to plasma-induced damage in a wiring process and this damage to the gate insulating film results in a change in a threshold voltage, etc. This phenomenon is referred to as antenna effect. To improve the reliability of the semiconductor device, suppressing the antenna effect is essential.

The antenna effect is suppressed in such a way that the charged particles accumulated on the interconnect are dispersed by electrically connecting a gate electrode of the SOI transistor formed in the circuit cell portion to a gate electrode of an anti-antenna-effect dummy fill-cell formed in a dummy fill-cell portion via an interconnect. This method, however, brings another problem that a gate leak current is generated at the anti-antenna-effect dummy fill-cell, leading to an increase in an active current at the SOI transistor.

<Structure of Semiconductor Device>

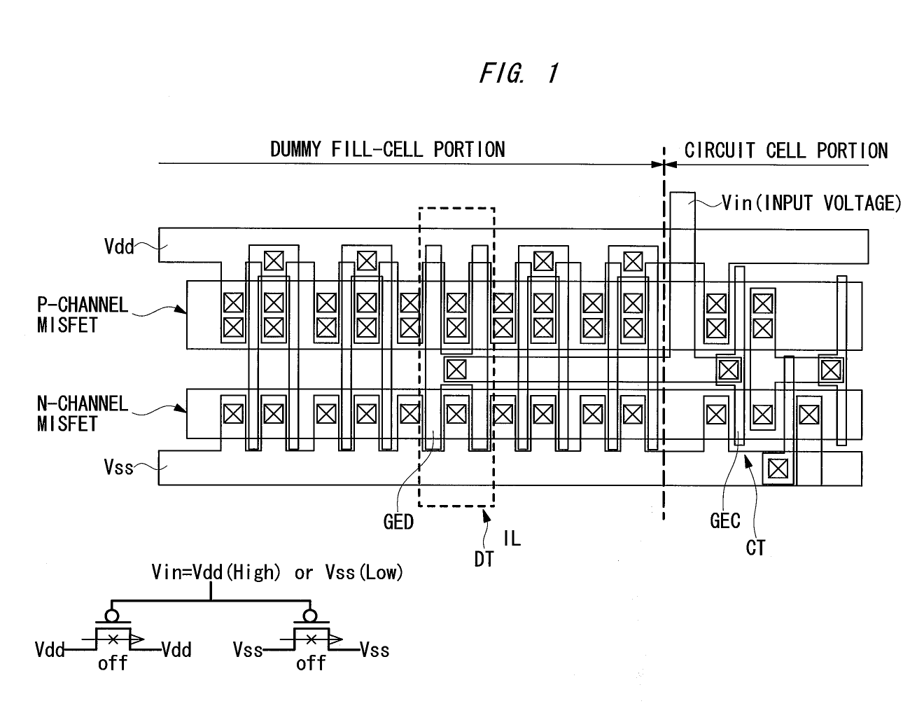

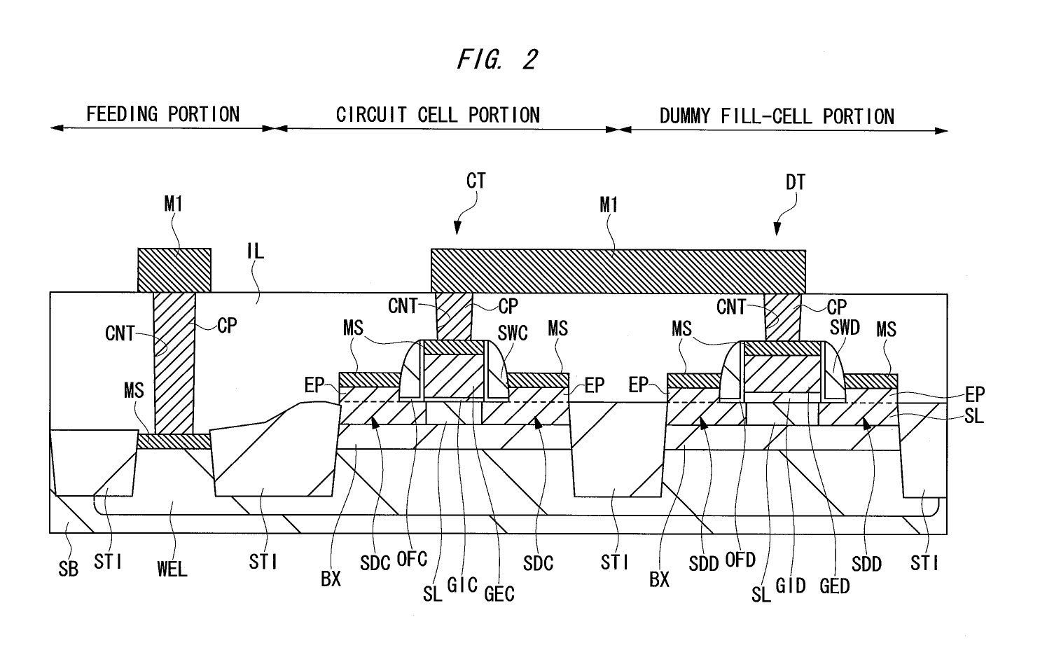

The structure of a semiconductor device according to a first embodiment will be described, referring to FIGS. 1 and 2. FIG. 1 is a plan view of main parts of the semiconductor device according to the first embodiment, and FIG. 2 is a cross-sectional view of the main parts of the semiconductor device according to the first embodiment. Out of various elements formed in the semiconductor device, an n-channel SOI transistor CT formed in a circuit cell portion and an anti-antenna-effect dummy fill-cell DT formed in a dummy fill-cell portion are illustrated in FIG. 2 as examples. The dummy fill-cell portion represents a region including no semiconductor element that originally contributes to circuit operations, or a region including fewer semiconductor elements contributing to circuit operations than other regions. In this region, to reduce the unevenness of the overall pattern density of the semiconductor device, a plurality of dummy fill-cells (dummy fills, dummy patterns, dummy cells) are arranged.

The SOI transistor CT and the anti-antenna-effect dummy fill-cell DT are formed on the main surface of an SOI substrate composed of a semiconductor substrate SB made of single-crystal silicon, an insulating film (buried insulating film, buried oxide film, BOX (Buried Oxide) film) BX made of silicon oxide that is formed on the semiconductor substrate SB, and a semiconductor layer (SOI layer, silicon layer) SL made of single-crystal silicon that is formed on the insulating film BX. The semiconductor substrate SB is a support substrate that supports the insulating film BX and a structure formed thereon. The insulating film BX is, for example, about 10 to 20 nm in thickness, and the semiconductor layer SL is, for example, also about 10 to 20 nm in thickness.

A p-type well WEL is formed in the semiconductor substrate SB, where a voltage from a feeding portion is applied to the well WEL. A plurality of element isolation portions STI are formed such that the element isolation portions STI isolate the circuit cell portion, the dummy fill-cell portion, and the feeding portion from each other, and such that, in the circuit cell portion and the dummy fill-cell portion, the element isolation portion STI isolates adjacent element forming regions from each other.

On the semiconductor layer SL of the circuit cell portion, a gate insulating film GIC of the SOI transistor CT and a gate electrode GEC of the SOI transistor CT are formed such that the gate electrode GEC is overlaid on the gate insulating film GIC. In the same manner, on the semiconductor layer SL of the dummy fill-cell portion, a gate insulating film GID of the anti-antenna-effect dummy fill-cell DT and a gate electrode GED of the anti-antenna-effect dummy fill-cell DT are formed such that the gate electrode GED is overlaid on the gate insulating film GID.

The gate insulating films GIC and GID are each made of, for example, a silicon oxide film or silicon oxynitride film. However, the thickness of the gate insulating film GID of the anti-antenna-effect dummy fill-cell DT is made larger than that of the gate insulating film GIC of the SOI transistor CT. The gate insulating film GID of the anti-antenna-effect dummy fill-cell DT is, for example, about 7 to 8 nm in thickness, while the gate insulating film GIC of the SOI transistor CT is, for example, about 2 to 3 nm in thickness.

The gate electrodes GEC and GED are each made of, for example, a conductive film, such as a polycrystal silicon film (polysilicon film, doped polysilicon film). In another case, the gate electrodes GEC and GED may be each made of a metal film or a metal compound film with metallic conductivity, such as a titanium nitride film. The gate width of the anti-antenna-effect dummy fill-cell DT is the same as that of the SOI transistor CT. However, the gate length of the anti-antenna-effect dummy fill-cell DT is larger than that of the SOI transistor CT, so that the gate area of the anti-antenna-effect dummy fill-cell DT is larger than that of the SOI transistor CT. The anti-antenna-effect dummy fill-cell DT and the SOI transistor CT have the same gate width of, for example, about 0.5 μm. The anti-antenna-effect dummy fill-cell DT has a gate length of, for example, about 0.21 μm, while the SOI transistor CT has a gate length of, for example, about 0.06 μm.

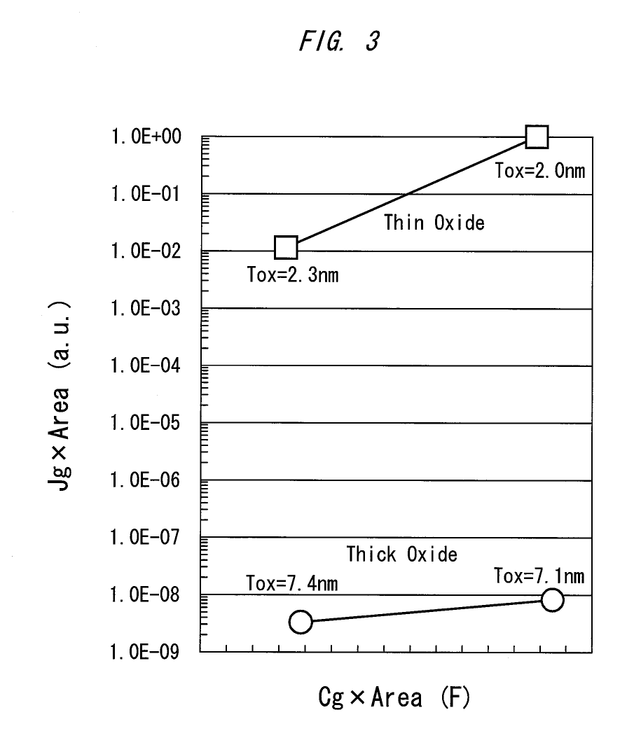

According to the first embodiment, to reduce the gate leak current of the anti-antenna-effect dummy fill-cell DT, the thickness of the gate insulating film GID of the anti-antenna-effect dummy fill-cell DT is determined to be larger than that of the gate insulating film GIC of the SOI transistor CT. However, to reduce the antenna effect, the gate area of the anti-antenna-effect dummy fill-cell DT is determined to be larger than that of the SOI transistor CT to make the gate capacity of the anti-antenna-effect dummy fill-cell DT almost equal to that of the SOI transistor CT. The gate leak currents and gate areas of the gate insulating films GIC and GID according to the first embodiment will be described in detail later, referring to FIG. 3.

The semiconductor layer SL below the gate electrode GEC serves as a region where a channel of the SOI transistor CT is formed. Side walls SWC are formed on the side walls of the gate electrode GEC via offset spacers OFC, respectively. Similarly, the semiconductor layer SL below the gate electrode GED serves as a region where a channel of the anti-antenna-effect dummy fill-cell DT is formed. Side walls SWD are formed on the side walls of the gate electrode GED via offset spacers OFD, respectively. The offset spacers OFC and OFD and the side walls SWC and SWD are made of insulating films. The offset spacers OFC and OFD are each made of, for example, a silicon oxide film, and the side walls SWC and SWD are each made of, for example, a silicon nitride film.

In the circuit cell portion, an epitaxial layer EP is formed selectively on a region of the semiconductor layer SL that is not covered with the gate electrode GEC, offset spacers OFC, and side walls SWC. In the dummy fill-cell portion, the epitaxial layer EP is also formed selectively on a region of the semiconductor layer SL that is not covered with the gate electrode GED, offset spacers OFD, and side walls SWD. In other words, the epitaxial layer EP is formed on both sides (in the gate length direction) of the gate electrode GEC of the SOI transistor CT via the offset spacers OFC and side walls SWC. Similarly, the epitaxial layer EP is formed on both sides (in the gate length direction) of the gate electrode GED of the anti-antenna-effect dummy fill-cell DT via the offset spacers OFD and side walls SWD.

The semiconductor layer SL and epitaxial layer EP on both sides (in the gate length direction) of the gate electrode GEC of the SOI transistor CT are formed as source/drain forming semiconductor regions SDC for the SOI transistor CT. In other words, in the semiconductor layer SL below the offset spacers OFC and side walls SWC, a pair of the source/drain forming semiconductor regions SDC are formed in areas separated from each other across the channel. Similarly, the semiconductor layer SL and epitaxial layer EP on both sides (in the gate length direction) of the gate electrode GED of the anti-antenna-effect dummy fill-cell DT are formed as source/drain forming semiconductor regions SDD for the anti-antenna-effect dummy fill-cell DT. In other words, in the semiconductor layer SL below the offset spacers OFD and side walls SWD, a pair of the source/drain forming semiconductor regions SDD are formed in areas separated from each other across the channel.

On the top (surface layer) of the source/drain forming semiconductor regions SDC of the circuit cell portion, of the source/drain forming semiconductor regions SDD for the dummy fill-cell portion, and of the well WEL of the feeding portion, a metal silicide layer MS is formed, which is a reaction layer (compound layer) made by reacting a metal with the semiconductor layer. The metal silicide layer MS is, for example, a cobalt silicide layer, nickel silicide layer, or nickel/platinum silicide layer. When the gate electrodes GEC and GED are each made of a polycrystal silicon film, the metal silicide layer MS is formed also on the top of the gate electrode GEC of the SOI transistor CT and of the gate electrode GED of the anti-antenna-effect dummy fill-cell DT.

On the SOI substrate, an inter-layer insulating film IL is formed such that it covers the gate electrodes GEC and GED, the offset spacers OFC and OFD, the side walls SWC and SWD, and the metal silicide layer MS. In the inter-layer insulating film IL, for example, contact holes CNT are formed such that they reach the metal silicide layer MS formed on the top of the gate electrode GEC of the SOI transistor CT, of the gate electrode GED of the anti-antenna-effect dummy fill-cell DT, and of the well WEL of the feeding portion. Other contact holes CNT (not illustrated) are also formed such that they reach the metal silicide layer MS formed on the top of the source/drain forming semiconductor regions SDC for the SOI transistor CT and of the source/drain forming semiconductor regions SDD for the anti-antenna-effect dummy fill-cell DT. Inside each of these contact holes CNT, a contact plug CP made of, for example, tungsten is formed.

On the inter-layer insulating film IL, an interconnect M1 is formed, which is made of copper or aluminum. The interconnect M1 electrically connects the gate electrode GEC of the SOI transistor CT to the gate electrode GED of the anti-antenna-effect dummy fill-cell DT.

Like a different dummy fill-cell formed in the dummy fill-cell portion, the anti-antenna-effect dummy fill-cell IDT is configured such that it does not operate even when a high input voltage (Vin) (e.g., high voltage (Vdd)) or a low input voltage (e.g., low voltage (Vss)) is applied to the gate electrode GED, as shown in FIG. 1.

As described above, by determining the thickness of the gate insulating film GID of the anti-antenna-effect dummy fill-cell DT to be larger than that of the gate insulating film GIC of the SOI transistor CT, the gate leak current (leak current flowing between the gate electrode CED and the source/drain forming semiconductor regions SDD) of the anti-antenna-effect dummy fill-cell DT is reduced.

Generally, however, a thicker gate insulating film of an MIS transistor reduces its gate leak current per unit area, but also reduces its gate capacity per unit area. If the thickness of the gate insulating film GID of the anti-antenna-effect dummy fill-cell DT is determined to be larger than that of the gate insulating film GIC of the SOI transistor CT, therefore, the gate capacity per unit area of the anti-antenna-effect dummy fill-cell DT becomes smaller than that of the SOI transistor CT. As a result, charged particles accumulate easily at the SOI transistor CT, which makes it impossible to suppress the antenna effect.

To prevent such a case, the gate capacity of the anti-antenna-effect dummy fill-cell DT must be made almost equal to that of the SOI transistor CT. According to the first embodiment, the gate capacity of the anti-antenna-effect dummy fill-cell DT is made almost equal to that of the SOI transistor CT by determining the gate area of the anti-antenna-effect dummy fill-cell DT to be larger than that of the SOI transistor CT. In this configuration, the gate leak current of the anti-antenna-effect dummy fill-cell DT is reduced and at the same time, the antenna effect is suppressed.

The effect of the gate area (gate length×gate width) of the MIS transistor on its gate leak current will be described. In the following description, a relatively thin gate insulating film of about 2 to 3 nm in thickness is referred to as a thin-film gate insulating film, and a relatively thick gate insulating film of about 7 to 8 nm in thickness is referred to as a thick-film gate insulating film.

The gate leak current per unit area (Jg) of an MIS transistor having a thin-film gate insulating film is larger than that of an MIS transistor having a thick-film gate insulating film (Jg (thin-film gate insulating film)>Jg (thick-film gate insulating film)). The gate capacity per unit area (Cg) of an MIS transistor having a thin-film gate insulating film is larger than that of an MIS transistor having a thick-film gate insulating film (Cg (thin-film gate insulating film)>Cg (thick-film gate insulating film)). To determine the gate capacity of an MIS transistor having a thin-film gate insulating film to be equal to that of an MIS transistor having a thick-film gate insulating film, therefore, the gate area of the MIS transistor having the thick-film gate insulating film must be made larger than that of the MIS transistor having the thin-film gate insulating film.

For example, when the gate capacity per unit area (Cg) of the MIS transistor having the thin-film gate insulating film is 10 pF/cm² and the same of the MIS transistor having the thick-film gate insulating film is 5 pF/cm², the gate area (gate length×gate width) of the MIS transistor having the thin-film gate insulating film must be determined to be 2 cm² and the same of the MIS transistor having the thick-film gate insulating film must be determined to be 4 cm². By determining the gate areas in such a manner, the gate capacity of the MIS transistor having the thin-film gate insulating film is made equal to that of the MIS transistor having the thick-film gate insulating film.

In this case, the gate leak current (Ig) of the MIS transistor having the thin-film gate insulating film and the gate leak current (Ig) of the MIS transistor having the thick-film gate insulating film are given as the following.

Ig (thin-film gate insulating film)=Jg (thin-film gate insulating film)×2 cm²

Ig (thick-film gate insulating film)=Jg (thick-film gate insulating film)×4 cm²

Generally, the gate leak current per unit area (Jg) of an MIS transistor having a thick-film gate insulating film of about 7 to 8 nm in thickness becomes smaller than that of an MIS transistor having a thin-film gate insulating film of about 2 to 3 nm in thickness in unit of digits. Because of this huge gate leak current reduction, even if the gate area of the MIS transistor having the thick-film gate insulating film is determined to be 2 to 4 times as large as the gate area of the MIS transistor having the thin-film gate insulating film, the gate leak current (Ig) of the MIS transistor having the thick-film gate insulating film is still extremely smaller than that of the MIS transistor having the thin-film gate insulating film.

FIG. 3 is a graph showing an example of the relationship between the leak currents (Jg×Area) of an MIS transistor having a thick-film gate insulating film and an MIS transistor having a thin-film gate insulating film, the leak currents flowing from respective gates to sources/drains of both MIS transistors, and the gate capacities (Cg×Area) of both MIS transistors. In the graph, Jg denotes the gate leak current per unit area of the MIS transistor, Cg denotes the gate capacity per unit area of the MIS transistor, and Area denotes the gate area of the MIS transistor.

As shown in FIG. 3, comparing an MIS transistor having a thin-film gate insulating film (e.g., Tox=2.3 nm) with an MIS transistor having a thick-film gate insulating film (e.g., Tox=7.4 nm), both MIS transistors having almost the same gate capacity, reveals that the gate leak current (Ig=Jg×Area) of the latter MIS transistor is smaller than that of the former MIS transistor by 6 digits or more.

According to the first embodiment, the thickness of the gate insulating film GID of the anti-antenna-effect dummy fill-cell DT is determined to be, for example, about 7 to 8 nm, and the thickness of the gate insulating film GIC of the SOI transistor CT is determined to be, for example, about 2 to 3 nm. Even if the gate area of the anti-antenna-effect dummy fill-cell DT is determined to be 2 to 4 times as large as that of the SOI transistor CT so as to make the gate capacity of the anti-antenna-effect dummy fill-cell DT almost equal to that of the SOI transistor CT, the gate leak current (Ig) of the anti-antenna-effect dummy fill-cell DT is still smaller than that of the SOI transistor CT by approximately 6 to 8 digits.

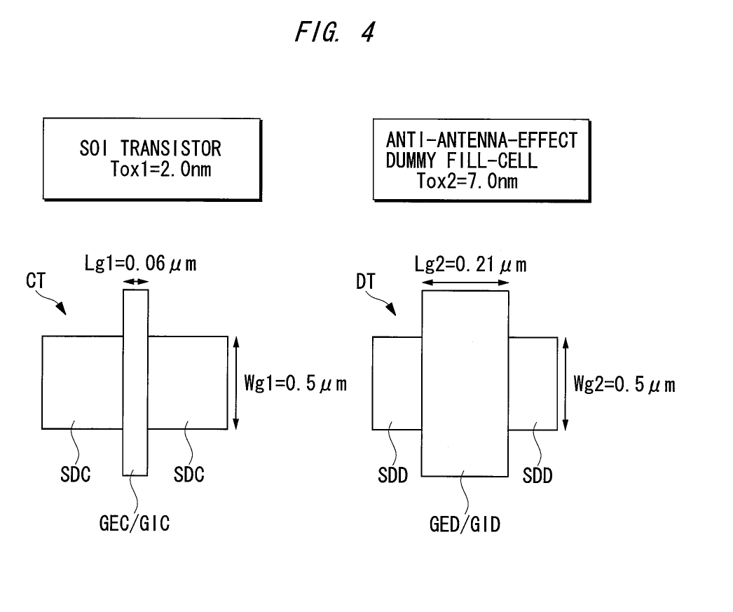

FIG. 4 is a schematic plan view of an example of the dimensions of the SOI transistor and the anti-antenna-effect dummy fill-cell according to the first embodiment.

The SOI transistor CT has the gate insulating film GIC of 2.0 nm in thickness (Tox1), a gate length (Lg1) of 0.06 μm, and a gate width (Wg1) of 0.5 μm. Hence, the gate capacity (Cox1) of the SOI transistor CT is given as the following.

$$\begin{matrix}Cox 1 = ɛ ox \times Lg 1 \times Wg 1 / Tox 1 \\ = ɛ ox \times 0.06 ( µm ) \times 0.5 ( µm ) / 2 ( µm ) \\ = ɛ ox \times 0.015 \times {10}^{- 3} ( m ) \end{matrix}$$

The anti-antenna-effect dummy fill-cell DT has the gate insulating film GID of 7.0 nm in thickness (Tox 2), a gate length (Lg2) of 0.21 μm, and a gate width (Wg2) of 0.5 μm. Hence, the gate capacity (Cox2) of the anti-antenna-effect dummy fill-cell DT is given as the following.

$$\begin{matrix}Cox 2 = ɛ ox \times Lg 2 \times Wg 2 / Tox 2 \\ = ɛ ox \times 0.21 ( µm ) \times 0.5 ( µm ) / 7 ( µm ) \\ = ɛ ox \times 0.015 \times {10}^{- 3} ( m ) \end{matrix}$$

This gate capacity Cox2 is the same as the gate capacity (Cox1) of the SOI transistor CT.

The example in which the gate area of the anti-antenna-effect dummy fill-cell DT is made larger than that of the SOI transistor CT by increasing the gate length of the anti-antenna-effect dummy fill-cell DT has been explained in the above description. The gate area of the anti-antenna-effect dummy fill-cell DT may be increased by increasing the gate width of the same or by increasing both gate length and gate width of the same.

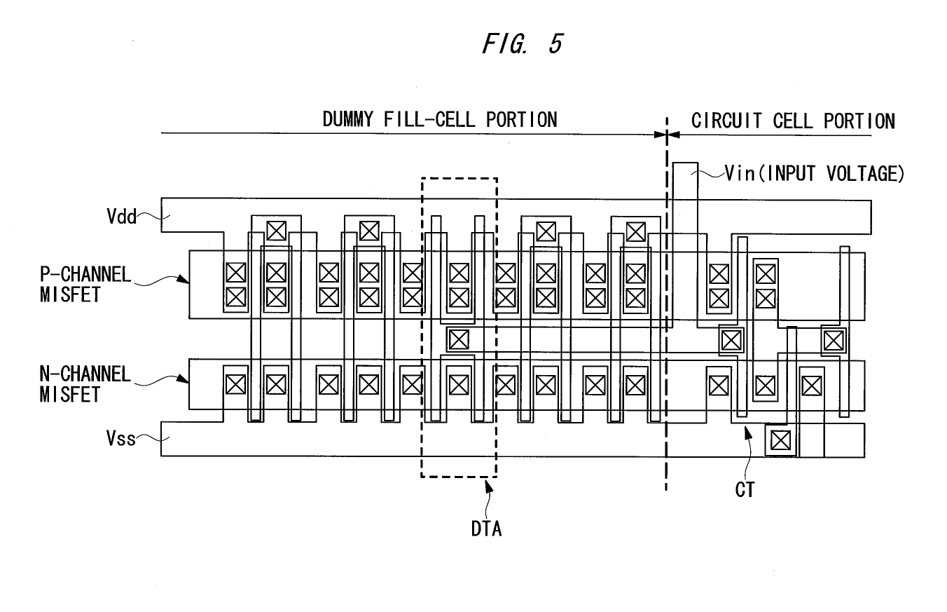

FIG. 5 is a plan view of main parts of a semiconductor device including a conventional anti-antenna-effect dummy fill-cell examined by the inventors.

As shown in FIG. 5, a conventional anti-antenna-effect dummy fill-cell DTA is formed to be identical in dimensions with a different dummy fill-cell. In the dummy fill-cell portion, gate electrodes of all dummy fill-cells including the anti-antenna-effect dummy fill-cell DTA are arranged across given intervals, which means that the occupation rate of all dummy fill-cells including the anti-antenna-effect dummy fill-cell DTA is not 100%.

Therefore, even if the gate length of the anti-antenna-effect dummy fill-cell DT is increased as shown in FIG. 1, it is not necessary to increase the overall area of the dummy fill-cell portion, in which case an increase in the area of the semiconductor device does not result.

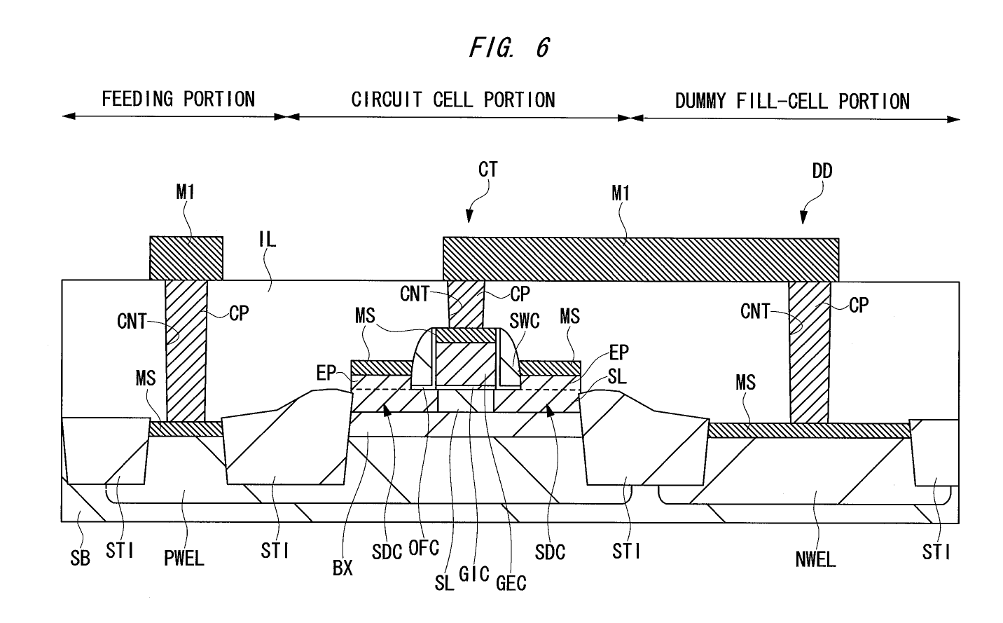

FIG. 6 is a cross-sectional view of main parts of a semiconductor device including a protective diode examined by the inventors. In FIG. 6, NWEL denotes an n-type well and PWEL denotes a p-type well.

To suppress the antenna effect, the anti-antenna-effect dummy fill-cell DT of FIG. 1 in the dummy fill-cell portion may be replaced with a protective diode DD. However, providing the protective diode DD raises a concern that when a substrate bias from the feeding portion is applied, the gate voltage of the SOI transistor CT may be changed via the protective diode DD. The anti-antenna-effect dummy fill-cell DT of the first embodiment offers an advantage that such a change in the gate voltage of the SOI transistor CT does not occur.

As described above, according to the first embodiment, the gate leak current of the anti-antenna-effect dummy fill-cell DT is reduced by determining the thickness of the gate insulating film GID of the anti-antenna-effect dummy fill-cell DT to be larger than that of the gate insulating film GIC of the SOI transistor CT. In addition, the gate capacity of the anti-antenna-effect dummy fill-cell DT is made almost equal to that of the SOI transistor CT by determining the gate area of the anti-antenna-effect dummy fill-cell DT to be larger than that of the SOI transistor CT. This suppresses the antenna effect. Hence the semiconductor device including the SOI substrate reduces the gate leak current of the anti-antenna-effect dummy fill-cell DT and suppresses the antenna effect.

<Manufacturing Method for Semiconductor Device>

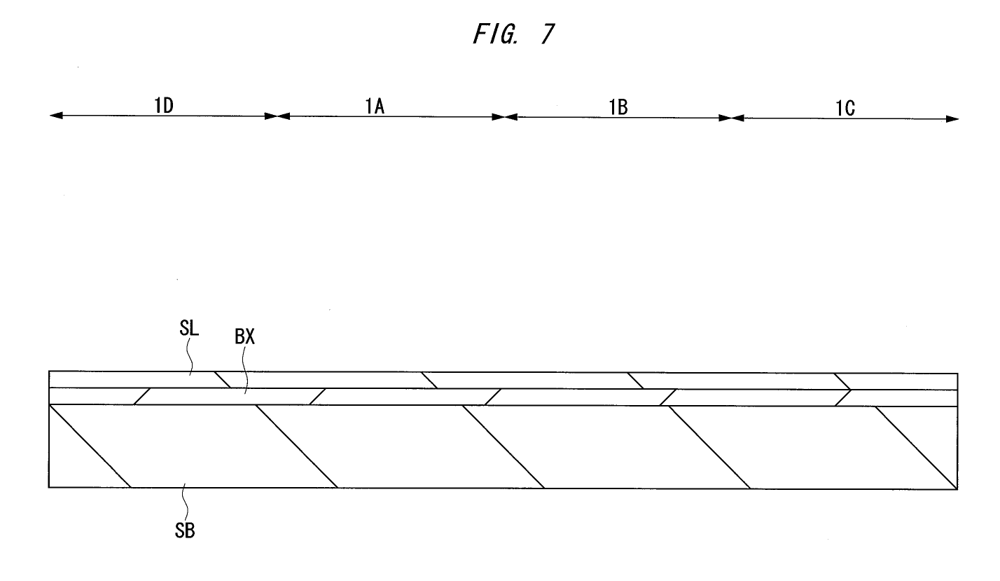

A manufacturing method for the semiconductor device according to the first embodiment will then be described in the order of processes, referring to FIGS. 7 to 25. FIGS. 7 to 25 are cross-sectional views of main parts of the semiconductor device according to the first embodiment during manufacturing processes.

In the first embodiment, a region where an SOI transistor (n-channel SOI transistor or p-channel SOI transistor) is formed is referred to as a SOI region 1A, and a region where a bulk transistor (n-channel bulk transistor or p-channel bulk transistor) is formed is referred to as a bulk region 1C. In the SOI region 1A, the SOI transistor is formed on the main surface of an SOI substrate composed of a semiconductor substrate, an insulating film on the semiconductor substrate, and a semiconductor layer on the insulating film. In the bulk region 1C, the bulk transistor is formed on the main surface of the semiconductor substrate. A region where an anti-antenna-effect dummy fill-cell is formed is referred to as a dummy fill-cell region 1B, and a region where a feeding portion is formed is referred to as a feeding region 1D.

Manufacturing of the n-channel SOI transistor and the n-channel bulk transistor will be described, and description of manufacturing of the p-channel SOI transistor and the p-channel bulk transistor will be omitted. An example of simultaneous formation of a gate insulating film of the anti-antenna-effect dummy fill-cell and a gate insulating film of the bulk transistor will be described. Formation of gate insulating films is, however, not limited to this example. That is, the gate insulating film of the anti-antenna-effect dummy fill-cell may be formed by a process different from a process of forming the gate insulating film of the bulk transistor. However, simultaneous formation of the gate insulating film of the anti-antenna-effect dummy fill-cell and the gate insulating film of the bulk transistor offers an advantage that an increase in the number of manufacturing processes is prevented. Those cross-sectional views for reference in description of the manufacturing method of the first embodiment do not exactly indicate the size relation between various films having thicknesses so that the cross-sectional views are simpler and more understandable.

As shown in FIG. 7, the semiconductor substrate SB on which the insulating film BX and the semiconductor layer SL are stacked in order is prepared. The semiconductor substrate SB is a support substrate made of single-crystal Si (silicon). The insulating film BX on the semiconductor substrate SB is made of silicon oxide, and the semiconductor layer SL on the insulating film BX is made of single-crystal silicon having resistance of about 1 to 10 Ωcm. The insulating film BX is, for example, 10 to 20 nm in thickness, and the semiconductor layer SL is, for example, 10 to 20 nm in thickness.

The SOI substrate can be formed by, for example, an SIMOX (Silicon Implanted Oxide) method or laminating method. The SOI substrate is formed by the SIMOX method in such a way that O₂ (oxygen) ions in their high-energy state are implanted into the main surface of a semiconductor substrate made of Si (silicon), which is followed by a heat treatment by which Si (silicon) and O₂ (oxygen) are bonded together to form a buried oxide film (BOX film) in a location slightly deeper inside the semiconductor substrate than its main surface. The SOI substrate is formed by the laminating method in such a way that an Si (silicon)-made semiconductor substrate having an oxide film (BOX film) formed on its upper surface and another Si (silicon)-made semiconductor substrate are bonded together by applying high heat and pressure to the semiconductor substrates and then one of them is polished into a thin film.

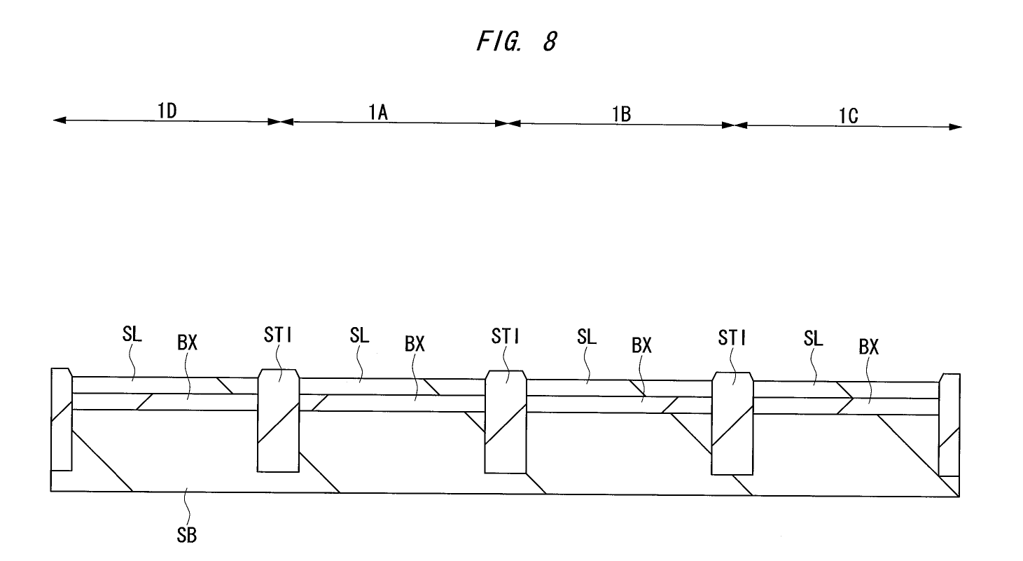

Subsequently, as shown in FIG. 8, element isolation portions STI each made of an insulating film having an STI (Shallow Trench Isolation) structure are formed in the SOI substrate.

In a process of forming the element isolation portions STI, a hard mask pattern made of silicon nitride is formed on the semiconductor layer SL and then dry etching is performed, using the hard mask pattern as a mask, to form a plurality of trenches extending from the upper surface of the semiconductor layer SL to the middle depth of the semiconductor substrate SB. The semiconductor layer SL and insulating film BX and the semiconductor substrate SB are opened to form the plurality of trenches. Subsequently, a liner oxide film is formed on the interior of the trenches, and then an insulating film made of, for example, silicon oxide, is formed on the semiconductor layer SL including the inside of the trenches by, for example, CVD (Chemical Vapor Deposition). The upper surface of this insulating film is then polished by, for example, CMP (Chemical Mechanical Polishing) to leave the insulating film inside the trenches, after which the hard mask pattern is eliminated. Through this process, the element isolation portions STI are formed.

The element isolation portions STI are inactive regions that isolate a plurality of active regions from each other. In other words, in a plan view, the shape of active regions is defined by element isolation portions STI surrounding the active regions. A plurality of element isolation portions STI are formed such that they isolate the SOI region 1A, the dummy fill-cell region 1B, the bulk region 1C, and the feeding region 1D from each other, and in each of the SOI region 1A and the bulk region 1C, a plurality of element isolation portions STI are formed such that they isolate adjacent element forming regions from each other.

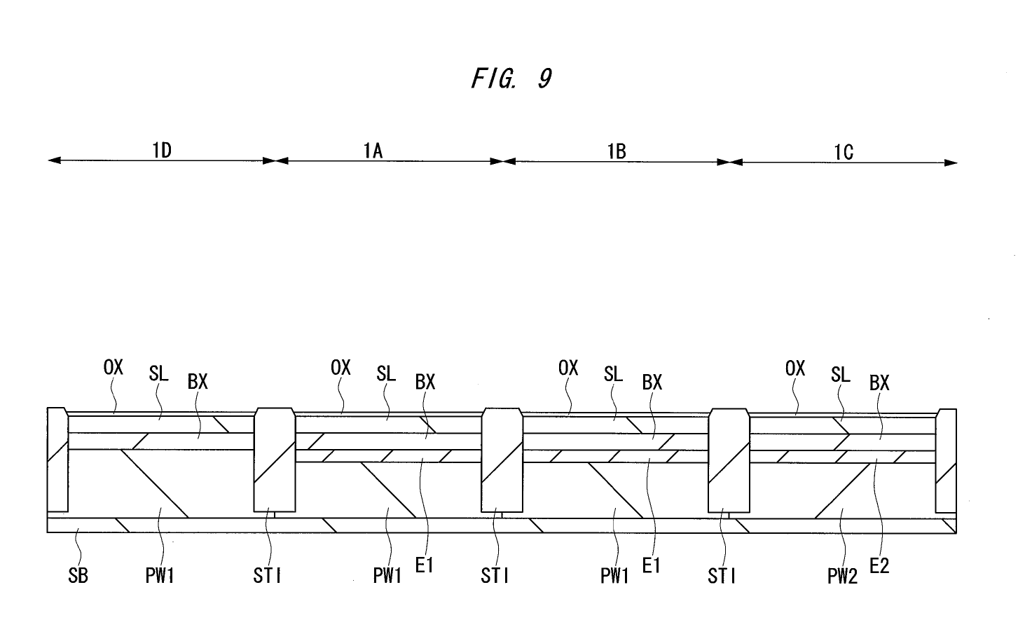

Subsequently, as shown in FIG. 9, an insulating film OX made of, for example, silicon oxide is formed on the semiconductor layer SL by, for example, a thermal oxidation method. The insulating film OX may be formed by leaving part of the above-described hard mask pattern made of silicon nitride as it is.

Subsequently, in the SOI region 1A, the dummy fill-cell region 1B, and the feeding region 1D, p-type impurity ions are implanted through the insulating film OX, the semiconductor layer SL, and the insulating film BX to selectively form p-type wells PW1 in desired regions of the semiconductor substrate SB. In the SOI region 1A and the dummy fill-cell region 1B, prescribed impurity ions are implanted through the insulating film OX, the semiconductor layer SL, and the insulating film EX to selectively form threshold voltage control/diffusion regions E1 in desired regions of the semiconductor substrate SB.

Then, in the bulk region 1C, p-type impurity ions are implanted through the insulating film OX, the semiconductor layer SL, and the insulating film BX to selectively form a p-type well PW2 in a desired region of the semiconductor substrate SB, and prescribed impurity ions are also implanted to selectively form a threshold voltage control/diffusion region E2 in a desired region of the semiconductor substrate SB.

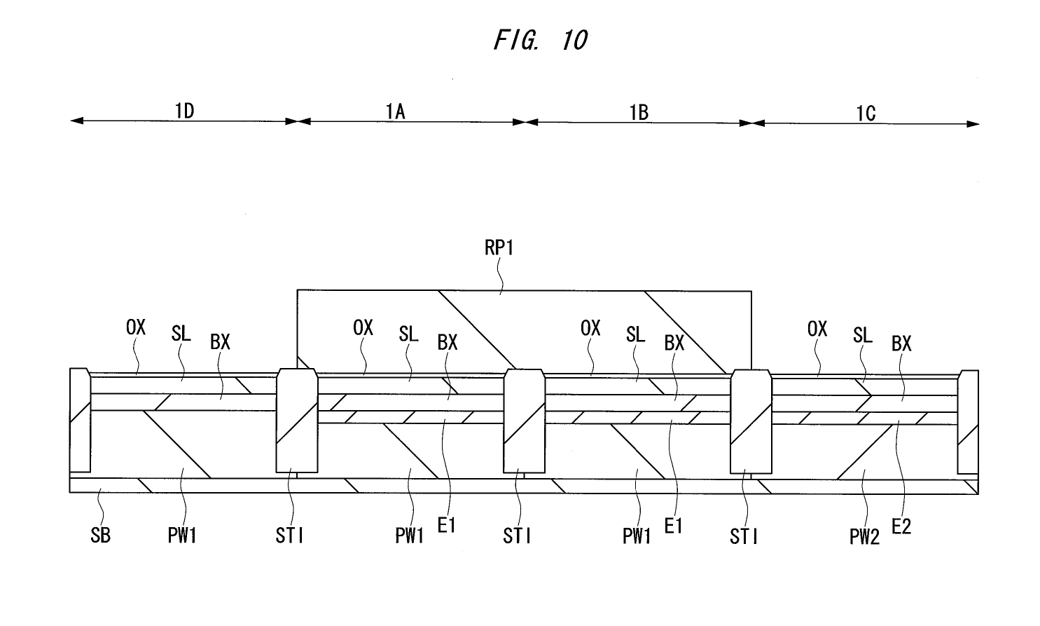

Subsequently, as shown in FIG. 10, a photoresist pattern RP1 is formed in the SOI region 1A and the dummy fill-cell region 1B by, for example, a lithographic method. Specifically, a film of photoresist is applied to the SOI substrate to form the photoresist pattern RP1 with openings formed in the bulk region 1C and the feeding region 1D. The photoresist pattern RP1 is formed such that it overlaps on an element isolation portion STI at the boundary between the bulk region 1C and a different region (SOI region 1A or dummy fill-cell region 1B) and on an element isolation portion STI at the boundary between the feeding region 1D and a different region (SOI region 1A or dummy fill-cell region 1B).

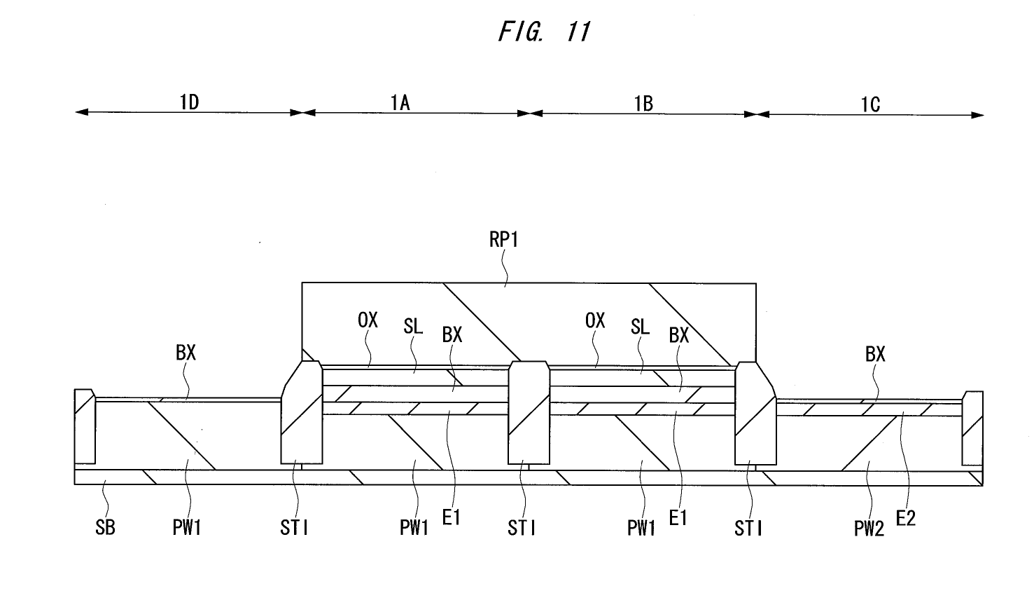

Subsequently, as shown in FIG. 11, the insulating film OX of the bulk region 1C and the feeding region 1D is eliminated by, for example, hydrofluoric acid cleansing. This hydrofluoric acid cleansing also partially eliminates the upper part of element isolation portions STI in the bulk region 1C and the feeding portion 1D. In the bulk region 1C and the feeding region 1D, therefore, level differences between the semiconductor substrate SB and the element isolation portions STI can be adjusted and level differences created on the element isolation portions STI at the boundaries between the element isolation portions STI and the photoresist pattern RP1 can be smoothened.

Subsequently, the semiconductor layer SL in the bulk region 1C and the feeding region 1D is selectively eliminated, using the insulating film BX as a stopper, by, for example, dry etching, and then the photoresist pattern RP1 is eliminated. Then, if necessary, a sacrificial oxidation method may be performed, by which after the insulating film BX in the bulk region 1C and the feeding region 1D is eliminated by, for example, hydrofluoric acid cleansing, a thermal oxidation film of, for example, about 10 nm in thickness is formed on the semiconductor substrate SB by, for example, a thermal oxidation method and then the formed thermal oxidation film is eliminated. By this sacrificial oxidation method, a damage layer introduced into the semiconductor substrate SB by the dry etching process for eliminating the semiconductor layer SL can be eliminated.

In regions formed by the above processes, a level difference between the upper surface of the semiconductor layer SL in the SOI region 1A and the dummy fill-cell region 1B and the upper surface of the semiconductor substrate SB in the bulk region 1C and the feeding region in turns out to be a small level difference of 20 nm. This small level difference allows the SOI transistor, the anti-antenna-effect dummy fill-cell, and the bulk transistor to be formed by the same process when a polycrystal silicon film, which will be made into a gate electrode, is deposited and processed. The small level difference is also effective for preventing incomplete smoothing of the level difference, wire breaking at the gate electrode, etc.

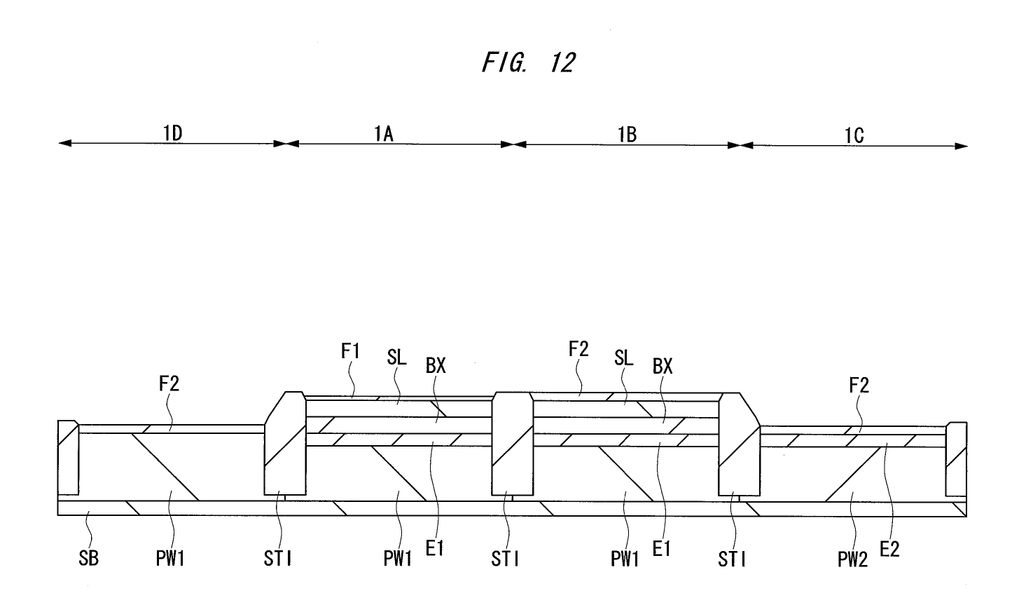

Subsequently, as shown in FIG. 12, a gate insulating film F1 is formed on the semiconductor layer SL in the SOI region 1A, and a gate insulating film F2 is formed on the semiconductor layer SL in the dummy fill-cell region 1B and on the semiconductor substrate SB in the bulk region 1C and the feeding region 1D. The gate insulating film F1 is, for example, about 2 to 3 nm in thickness, and the gate insulating film F2 is, for example, about 7 to 8 nm in thickness.

Specifically, the gate insulating film F1 in the SOI region 1A and the gate insulating film F2 in the dummy fill-cell region 1B, the bulk region 1C, and the feeding region 1D are formed in the following manner.

For example, the insulating film OX exposed in the dummy fill-cell region 1B and the insulating film DX exposed in the bulk region 1C and feeding region 1D are eliminated by hydrofluoric acid cleansing to expose the upper surface of the semiconductor layer SL in the dummy fill-cell region 1B and the upper surface of the semiconductor substrate SB in the bulk region 1C and feeding region 1D. Subsequently, using, for example, a thermal oxidation method, a thermal oxidation film of, for example, about 7.5 nm in thickness is formed on the semiconductor layer SL in the dummy fill-cell region 1B and on the semiconductor substrate SB in the bulk region 1C and the feeding region 1D.

By this process, the insulating film OX in the SOI region 1A is also eliminated to form a thermal oxidation film of, for example, about 7.5 nm in thickness on the semiconductor layer SL. This thermal oxidation film is selectively eliminated by, for example, a lithographic method and hydrofluoric acid cleansing and then is cleansed to remove etching residue, etching liquid, etc. Subsequently, a thermal oxidation film of, for example, about 2 nm in thickness is formed on the semiconductor layer SL in the SOI region 1A by, for example, a thermal oxidation method. Hence the gate insulating film F1 made of the thermal oxidation film of about 2 nm in thickness is formed on the semiconductor layer SL in the SOI region 1A, while the gate insulating film F2 made of the thermal oxidation film of about 7.5 nm in thickness is formed on the semiconductor layer SL in the dummy fill-cell region 1B and on the semiconductor substrate SB in the bulk region 1C and the feeding region 1D.

A nitride film of about 0.2 nm in thickness may be stacked on the thermal oxidation film of about 2 nm in thickness and the thermal oxidation film of about 7.5 nm in thickness by nitriding the upper surfaces of these thermal oxidation films with an NO gas. In such a case, the gate insulating film F1 composed of the nitride film and thermal oxidation film is formed on the semiconductor layer SL in the SOI region 1A while the gate insulating film F2 composed of the nitride film and thermal oxidation film is formed on the semiconductor substrate SB in the dummy fill-cell region 1B, the bulk region 1C, and the feeding region 1D.

In this manner, the gate insulating film F2 of the anti-antenna-effect dummy fill-cell is formed to be thicker than the gate insulating film F1 of the SOI transistor. As a result, the gate leak current of the anti-antenna-effect dummy fill-cell is reduced.

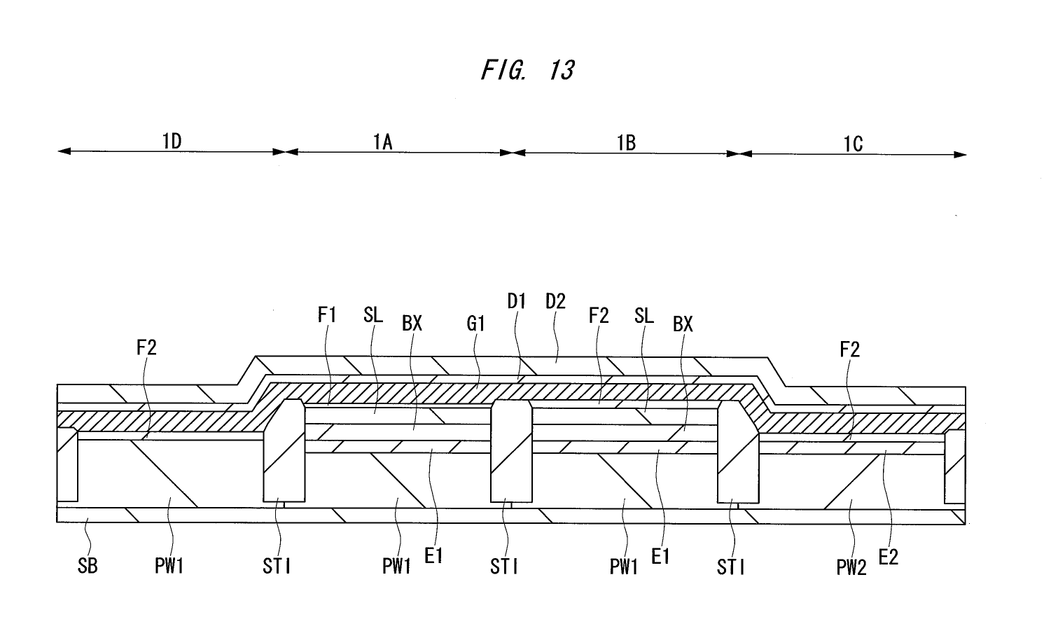

Subsequently, as shown in FIG. 13, a polycrystal silicon film G1, a silicon oxide film D1, and a silicon nitride film D2 are stacked in increasing order on the semiconductor substrate SB by, for example, CVD. The polycrystal silicon film G1 is, for example, about 50 nm in thickness, the silicon oxide film D1 is, for example, about 30 nm in thickness, and the silicon nitride film D2 is, for example, about 40 nm in thickness.

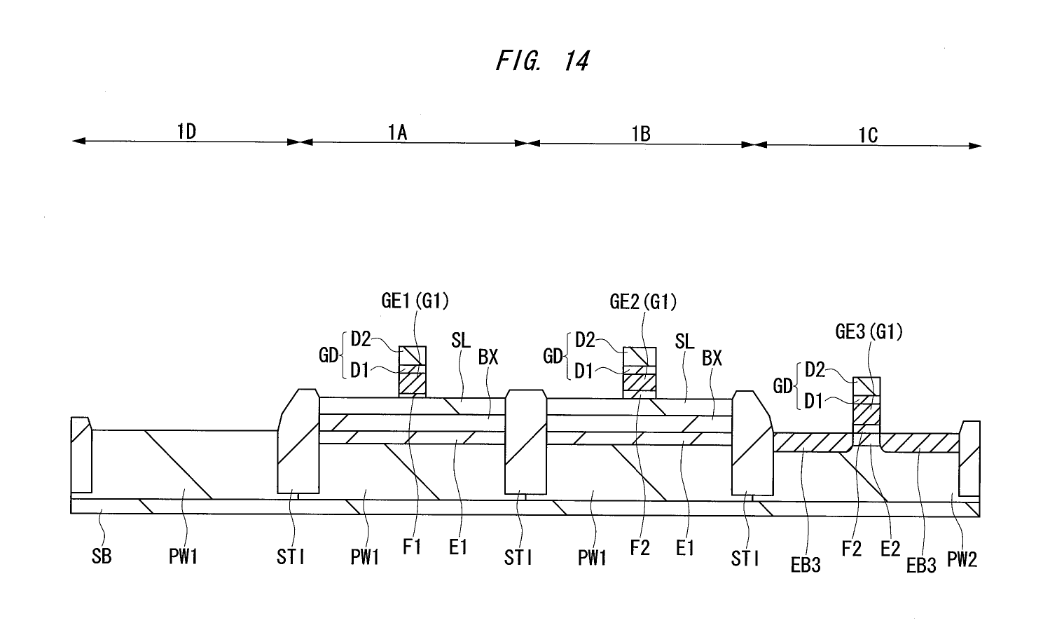

Subsequently, as shown in FIG. 14, the silicon nitride film D2, the silicon oxide film D1, and the polycrystal silicon film G1 are etched in order by, for example, a lithographic method and anisotropic dry etching. By this etching process, a gate protective film GD and a gate electrode GE1 of the SOI transistor, the gate protective film GD being composed of the silicon oxide film D1 and the silicon nitride film D2 and the gate electrode GE1 being composed of the polycrystal silicon film G1, are formed in the SOI region 1A. At the same time, a gate protective film GD and a gate electrode GE2 of the anti-antenna-effect dummy fill-cell, the gate protective film GD being composed of the silicon oxide film D1 and the silicon nitride film D2 and the gate electrode GE2 being composed of the polycrystal silicon film G1, are formed in the dummy fill-cell region 1B. At the same time, a gate protective film GD and a gate electrode GE3 of the bulk transistor, the gate protective film GD being composed of the silicon oxide film D1 and the silicon nitride film D2 and the gate electrode GE3 being composed of the polycrystal silicon film G1, are formed in the bulk region 1C. The silicon nitride film D2, the silicon oxide film D1, the polycrystal silicon film G1, and the gate insulating film F2 of the feeding region 1D are eliminated.

To make the gate capacity of the anti-antenna-effect dummy fill-cell equal to that of the SOI transistor, the gate electrode GE1 of the SOI transistor and the gate electrode GE2 of the anti-antenna-effect dummy fill-cell are formed such that the gate length of the anti-antenna-effect dummy fill-cell becomes larger than that of the SOI transistor. In another case, the gate capacity of the anti-antenna-effect dummy fill-cell is made equal to that of the SOI transistor by determining the gate width of the anti-antenna-effect dummy fill-cell to be larger than that of the SOI transistor.

As described above, the level difference between the upper surface of the semiconductor layer SL in the SOI region 1A and dummy fill-cell region 1B and the upper surface of the semiconductor substrate SB in the bulk region 1C and feeding region 1D is a small level difference of about 20 nm. This level difference is within a range of depth of focus of lithography. As a result, the gate protective film GD and the gate electrode GE1 of the SOI transistor, the gate protective film GD and the gate electrode GE2 of the anti-antenna-effect dummy fill-cell, and the gate protective film GD and the gate electrode GE3 of the bulk transistor can be formed simultaneously.

Subsequently, an n-type impurity, such as arsenic (As) ions, is implanted at an implantation rate of 3×10¹²/cm² with acceleration energy of 45 keV into the bulk region 1C. At this time, the impurity is not implanted into the gate electrode GE3 and a channel region under the gate electrode GE3 because of the presence of the silicon oxide film D1 and silicon nitride film D2 making up the gate protective film GD. As a result, an extension layer EB3 of the bulk transistor is formed in a self-aligning manner. During this ion implanting, the SOI region 1A, the dummy fill-cell region 1B, and the feeding region 1D are covered with a photoresist pattern and are therefore protected from the incoming ions, i.e., n-type impurity.

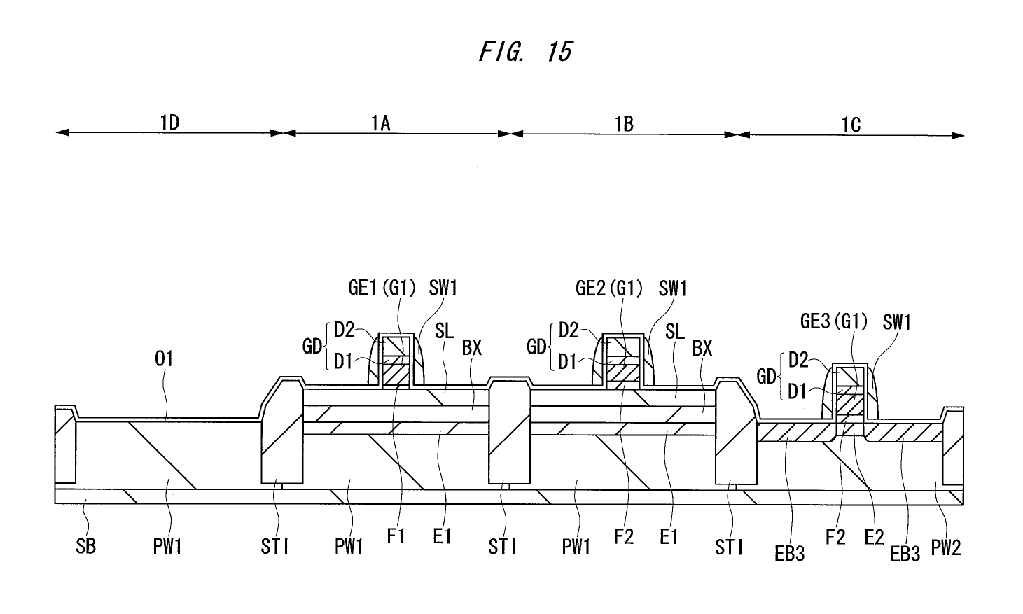

Subsequently, as shown in FIG. 15, a silicon oxide film O1 of, for example, about 10 nm in thickness and a silicon nitride film of, for example, about 40 nm in thickness are deposited by, for example, CVD and then the silicon nitride film is selectively etched by, for example, anisotropic dry etching. As a result, side walls SW1 made of the silicon nitride film are formed on the side faces of each of the gate electrode GE1 of the SOI transistor, the gate electrode GE2 of the anti-antenna-effect dummy fill-cell, and the gate electrode GE3 of the bulk transistor, via the silicon oxide film O1. According to this manufacturing method, the semiconductor layer SL is protected by the silicon oxide film O1. This prevents a film thickness reduction and damage introduction caused by dry etching.

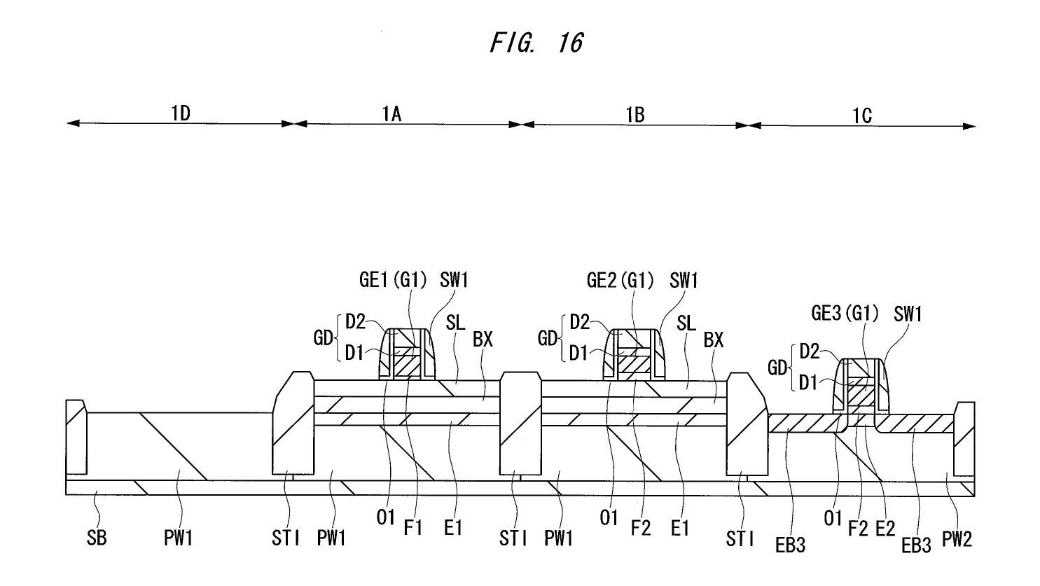

Subsequently, as shown in FIG. 16, the exposed silicon oxide film O1 is eliminated by hydrofluoric acid cleansing to expose the semiconductor layer SL, which is to serve as the sources/drains of the SOI transistor and anti-antenna-effect dummy fill-cell, and the semiconductor substrate SB, which is to serve as the source/drain of the bulk transistor. By this hydrofluoric acid cleansing, the silicon oxide film O1 of the feeding region 1D is also eliminated.

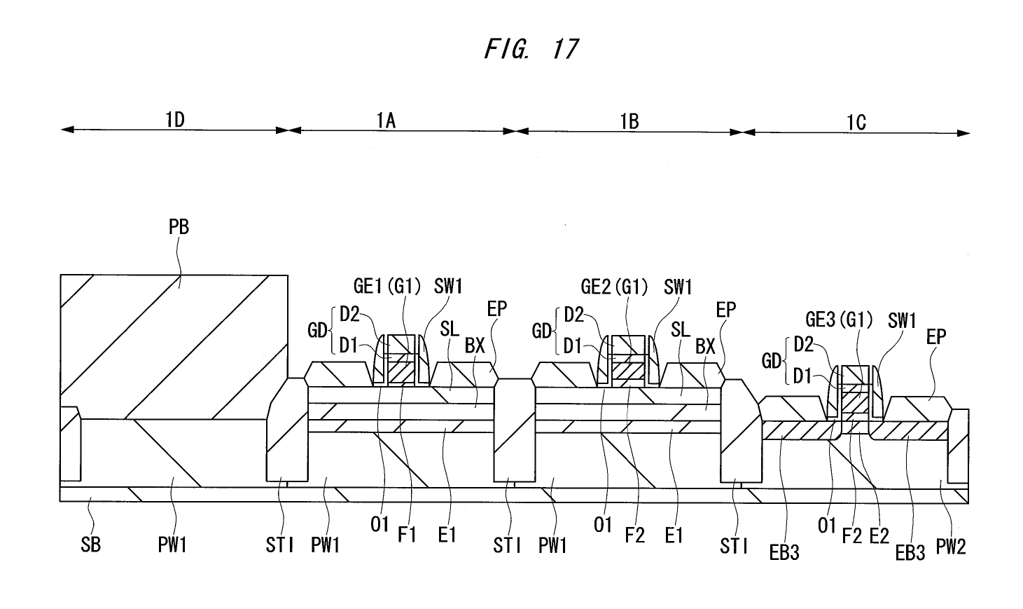

Subsequently, as shown in FIG. 17, after the feeding region 1D is covered with a protection film PB, a stacked single crystal layer made of Si (silicon) or SiGe (silicon germanium), i.e., epitaxial layer EP is selectively formed on the exposed semiconductor layer SL and semiconductor substrate SB, by, for example, a selective epitaxial growth method. The protection film PB is then eliminated.

The epitaxial layer EP is formed using, for example, a batch-type vertical epitaxial growth system in such a way that a boat carrying a plurality of semiconductor substrates is placed inside a furnace serving as a reaction chamber where the semiconductor substrates are subjected to an epitaxial growth process. A film-forming gas, such as SiH₄ (silane) gas, and an etching gas, such as chloride-atom-containing gas, are supplied into the furnace where the epitaxial growth process is advanced by the supplied gases. For example, an HCl (hydrochloric acid) gas or Cl (chlorine) gas may be used as the etching gas, i.e., chloride-atom-containing gas.

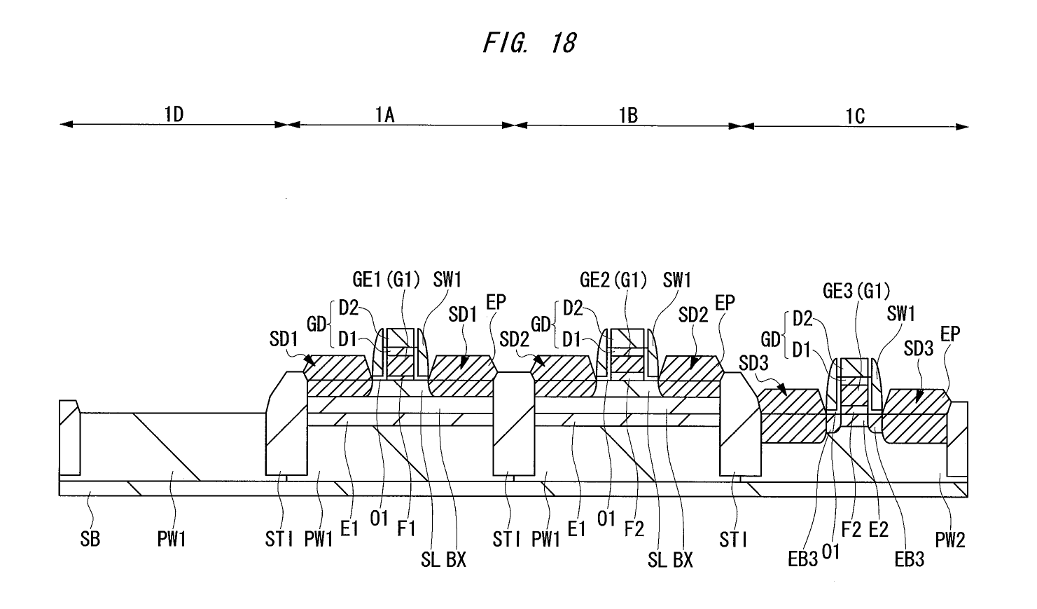

Subsequently, as shown in FIG. 18, an n-type impurity, such as arsenic (As) ions, is implanted at an implantation rate of 4×10¹⁵/cm² with acceleration energy of 11 keV into the SOI region 1A, the dummy fill-cell region 1B, and the bulk region 1C. As a result, a diffusion layer SD1 of the SOI transistor, a diffusion layer SD2 of the anti-antenna-effect dummy fill-cell, and a diffusion layer SD3 of the bulk transistor are formed in a self-aligning manner. Specifically, in the SOI transistor, the impurity is implanted into the epitaxial layer EP and the semiconductor layer SL under the epitaxial layer EP to form the diffusion layer SD1. In the anti-antenna-effect dummy fill-cell, the impurity is implanted into the epitaxial layer EP and the semiconductor layer SL under the epitaxial layer EP to form the diffusion layer SD2. In the bulk transistor, the impurity is implanted into the epitaxial layer EP and the semiconductor substrate SB under epitaxial layer EP to form the diffusion layer SD3.

At this time, the impurity is not implanted into the gate electrodes GE1, GE2, and GE3 and the channel regions under the gate electrodes GE1, GE2, and GE3 because of the presence of the silicon oxide films D1 and silicon nitride films D2 making up the gate protective films GD. During this ion implanting, the feeding region 1D is covered with a photoresist pattern and is therefore protected from the incoming ions, i.e., n-type impurity.

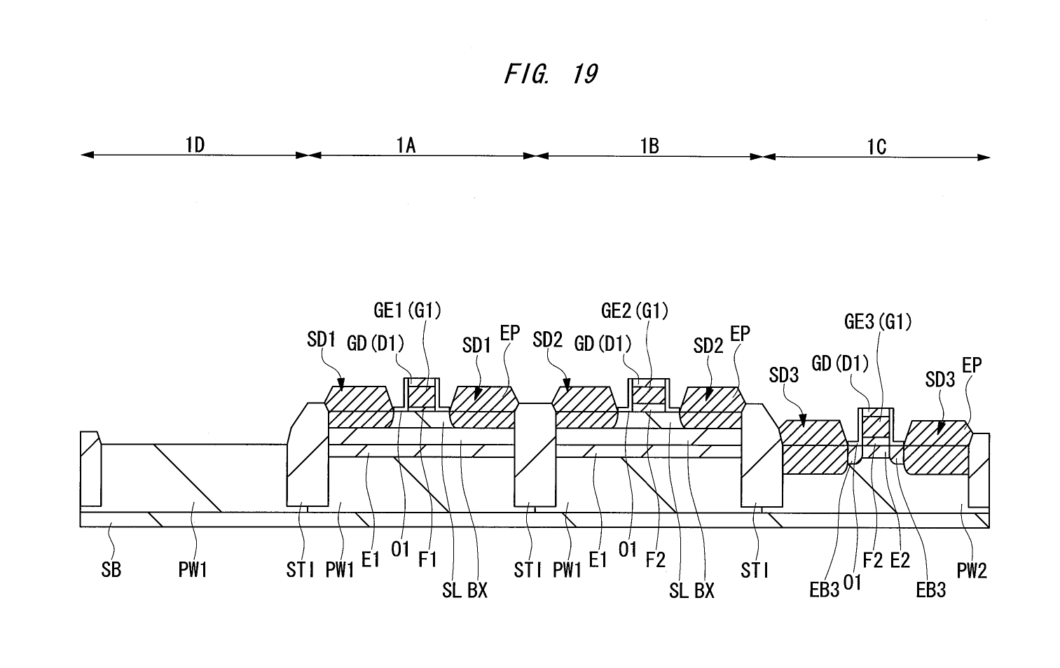

Subsequently, as shown in FIG. 19, the side walls SW1 and the silicon nitride films D2 making up the gate protection films DG are selectively eliminated by, for example, hot phosphoric acid cleansing.

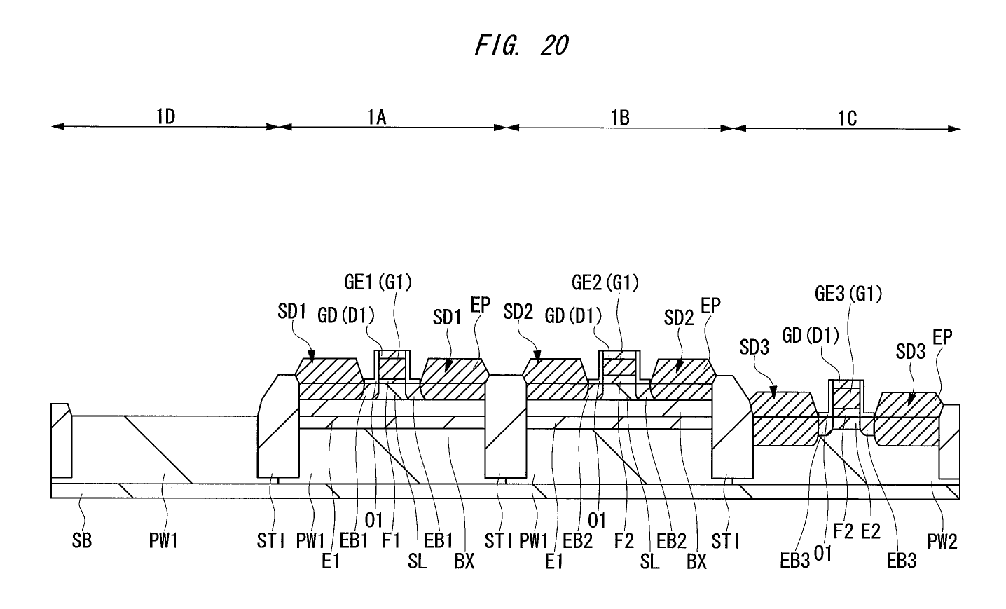

Subsequently, as shown in FIG. 20, an n-type impurity, such as arsenic (As) ions, is implanted at an implantation rate of 5×10¹⁵/cm² with acceleration energy of 4 keV into the SOI region 1A and the dummy fill-cell region 1B. As a result, an extension layer EB1 of the SOI transistor and an extension layer EB2 of the anti-antenna-effect dummy fill-cell are formed in a self-aligning manner.

At this time, the impurity is not implanted into the gate electrodes GE1 and GE2 and the channel regions under the gate electrodes GE1 and GE2 because of the presence of the silicon oxide films D1 making up the gate protective films GD. During this ion implanting, the bulk region 1C and the feeding region 1D are covered with a photoresist pattern and are therefore protected from the incoming ions, i.e., n-type impurity.

Subsequently, the implanted impurity is activated and thermally diffused by, for example, RTA (Rapid Thermal Annealing). The RAT is performed, for example, under a nitride atmosphere at 1050° C. By this thermal diffusion process, the distance between the gate electrode GE1 and the extension layer EB1 of the SOI transistor and the distance between the gate electrode GE2 and the extension layer EB2 of the anti-antenna-effect dummy fill-cell are controlled.

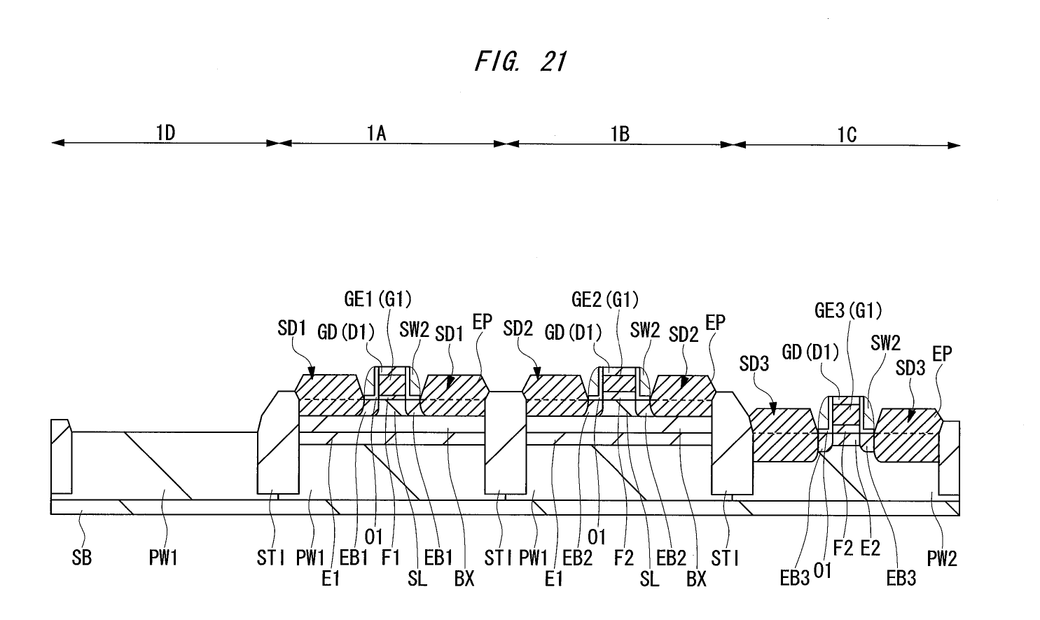

Subsequently, as shown in FIG. 21, a silicon nitride film of, for example, about 40 nm in thickness is deposited on the semiconductor substrate SB and then the silicon nitride film is etched by anisotropic dry etching. As a result, side walls SW2 made of the silicon nitride film are formed on the side faces of each of the gate electrodes GE1, GE2, and GE3, via the silicon oxide film O1.

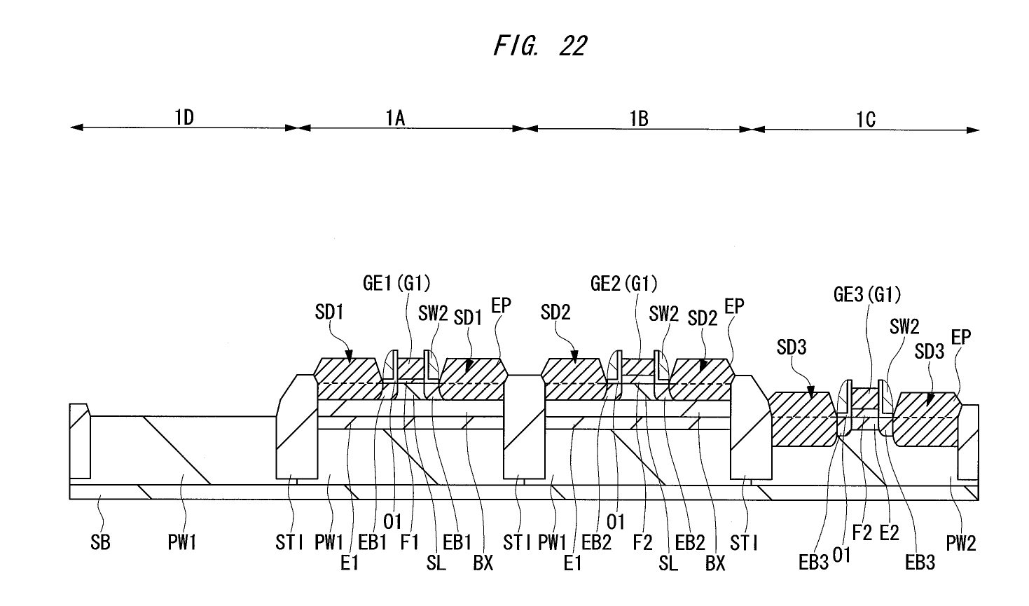

Subsequently, as shown in FIG. 22, the silicon oxide films D1 making up the gate protection films GD are selectively eliminated by, for example, hydrofluoric acid cleansing to expose the gate electrodes GE1, GE2, and GE3.

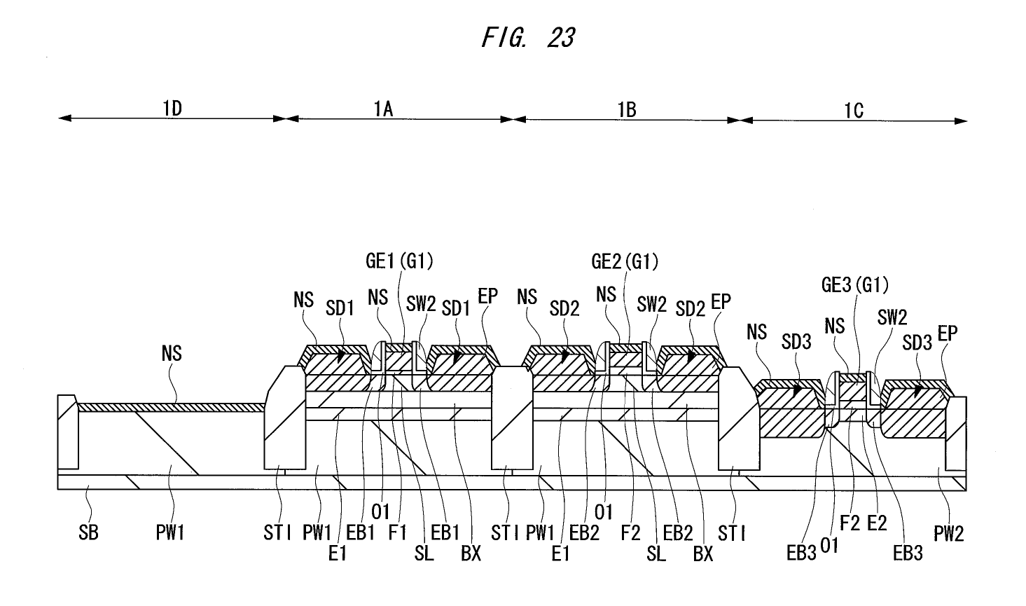

Subsequently, as shown in FIG. 23, a metal film, such as Ni (nickel) film, of about 20 nm in thickness is deposited on the semiconductor substrate SB by, for example, sputtering, and then the deposited nickel film is subjected to a heat treatment at approximately 320° C., by which Ni (nickel) and Si (silicon) react with each other to form a nickel silicide layer NS. Subsequently, an unreacted portion of Ni (nickel) is eliminated using, for example, a mixed solution of HCL (hydrochloric acid) and H₂O₂ (hydrogen peroxide water), after which the phase of the nickel silicide layer NS is controlled through a heat treatment at, for example, approximately 550° C.

As a result, the nickel silicide layer NS is formed on the top of the gate electrode GE1 and the diffusion layer SD1 of the SOI transistor in the SOI region 1A, on the top of the gate electrode GE2 and the diffusion layer SD2 of the anti-antenna-effect dummy fill-cell in the dummy fill-cell region 1B, and on the top of the gate electrode GE3 and the diffusion layer SD3 of the bulk transistor in the bulk region 1C. In the feeding region 1D, the nickel silicide layer NS is formed on the top of the semiconductor substrate SB.

Through the above process, the SOI transistor having the source/drain (extension layer EB1/diffusion layer SD1) and the gate electrode GE1 is formed in the SOI region 1A. Likewise, the anti-antenna-effect dummy fill-cell having the source/drain (extension layer EB2/diffusion layer SD2) and the gate electrode GE2 is formed in the dummy fill-cell region 1B. Likewise, the bulk transistor having the source/drain (extension layer EB3/diffusion layer SD3) and the gate electrode GE3 is formed in the bulk region 1C.

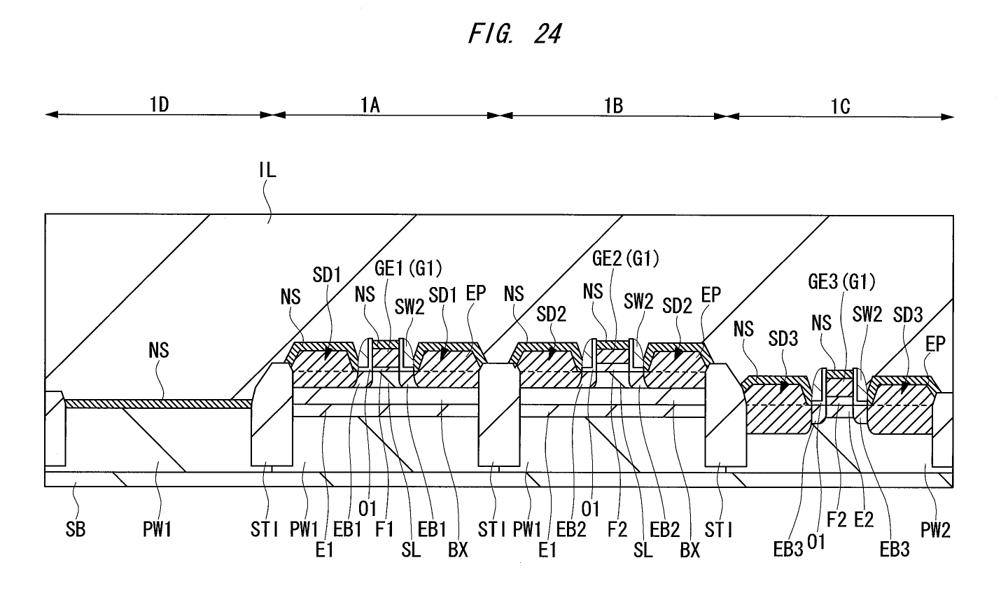

Subsequently, as shown in FIG. 24, an insulating film made of a silicon nitride film, which is used as an etching stopper, and an insulating film made of a silicon oxide film are deposited in order on the semiconductor substrate SB to form the inter-layer insulating film IL, whose the upper surface is then flattened.

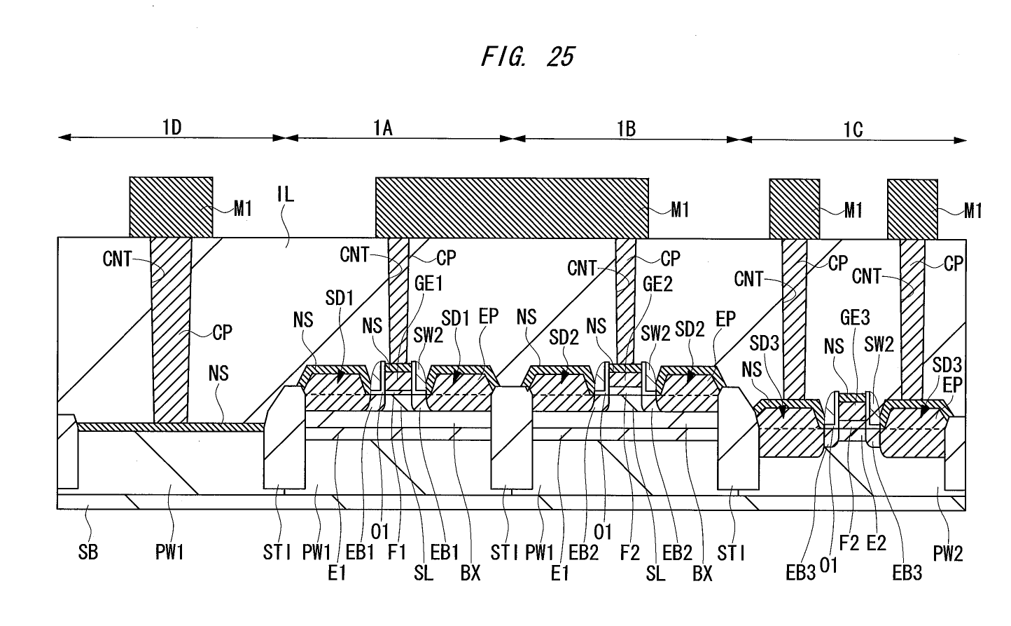

Subsequently, as shown in FIG. 25, contact holes CNT are formed such that they penetrate the inter-layer insulating film IL and reach the nickel silicide layers NS formed on the top of the gate electrode GE1 of the SOI transistor and the top of the gate electrode GE2 of the anti-antenna-effect dummy fill-cell, respectively. Other contact holes CNT are also formed such that they reach the nickel silicide layers NS formed on the top of the source/drain of the SOI transistor and on the top of the gate electrode GE3 and source/drain of the bulk transistor, respectively.

Subsequently, on the inter-layer insulating film IL including the interior of the contact holes, for example, a Ti (titanium)-containing barrier conductive film and a W (tungsten) film are formed in order by, for example, sputtering. The barrier conductive film and W (tungsten) film on the inter-layer insulating film IL are then eliminated by, for example, CMP to form columnar contact plugs CP inside the contact holes CNT, the contact plugs CP containing the W (tungsten) film as a main conductor.

Subsequently, a metal film, such as Cu (copper) or Al (aluminum) film, is formed on the semiconductor substrate SB and then is processed to form an interconnect M1 electrically connected to the contact plugs CP. The gate electrode GE1 of the SOI transistor is electrically connected to the gate electrode GE2 of the anti-antenna-effect dummy fill-cell via the formed interconnect M1. Hereafter, additional interconnects, etc., are then formed above the interconnect M1 to almost complete the semiconductor device according to the first embodiment.

### Second Embodiment

According to the first embodiment described above, the gate insulating film GID of the anti-antenna-effect dummy fill-cell DT is formed of a silicon oxide film or a silicon oxynitride film, as shown, for example, in FIG. 2. In another embodiment, however, a high dielectric constant film with a dielectric constant higher than that of the silicon nitride film, such as a film made of oxide (metal compound) of any one of Hf (hafnium), Zr (zirconium), Al (aluminum), Ti (titanium), etc., or silicate compound of any one of these substances, may be used in place of the silicon oxide film or the silicon oxynitride film, as the gate insulating film GID.

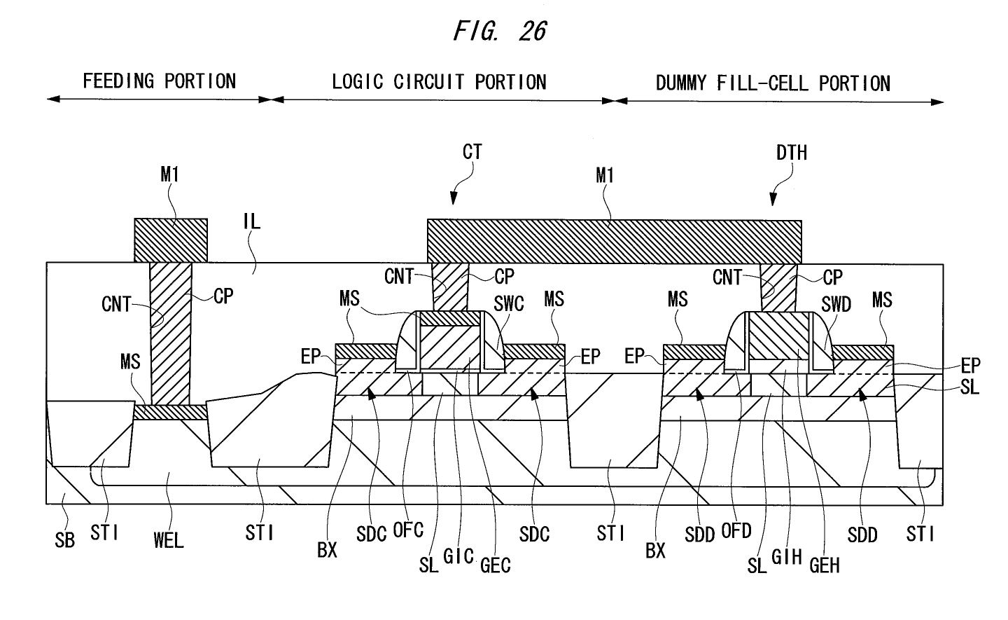

FIG. 26 is a cross-sectional view of main parts of a semiconductor device according to a second embodiment.

As shown in FIG. 26, a gate insulating film GIH of an anti-antenna-effect dummy fill-cell DTH is formed of a high dielectric constant film, while a gate insulating film GIC of the SOI transistor and a gate insulating film (not illustrated) of the bulk transistor are each formed of a silicon oxide film or a silicon oxynitride film.

In place of the silicon oxide film or the silicon oxynitride film, a high dielectric constant film is used as the gate insulating film GIH of the anti-antenna-effect dummy fill-cell DTH. This allows the anti-antenna-effect dummy fill-cell DTH identical in configuration with the above anti-antenna-effect dummy fill-cell of the first embodiment to accumulate charged particles in greater number. This reduces damage to the gate electrode GIC of the SOI transistor.

When the high dielectric constant film is used as the gate insulating film GIH, a gate electrode GEH of the anti-antenna-effect dummy fill-cell DTH should preferably be made of a metal film. A combination of the gate insulating film GIH made of a high dielectric constant film and the gate electrode GEH made of a polycrystal silicon film is apt to cause a problem with a contact surface, and tends to increase an operating voltage. The combination also leads to development of phonon vibration that hampers electron flows. However, by adopting a combination of the gate insulating film GIH made of a high dielectric constant film and the gate electrode GEH made of a metal film, the problem with the contact surface and the phonon vibration can be suppressed.

In this manner, by using the high dielectric constant film as the gate insulating film GIH of the anti-antenna-effect dummy fill-cell DTH, damage to the gate electrode GIC of the SOI transistor is reduced to be smaller than damage in the case of using the silicon oxide film or silicon oxynitride film.

As described above, the invention by the inventors has been specifically explained according to the embodiments, however, it is obvious that the invention is not limited to the embodiments and various changes may be made without departing from the scope of the invention.

What is claimed is:

1. A semiconductor device comprising:
an SOI substrate including a semiconductor substrate, an insulating film on the semiconductor substrate, and a semiconductor layer on the insulating film;
a first field-effect transistor formed in a first region of the SOI substrate;
a dummy fill-cell formed in a second region different from the first region of the SOI substrate; and
an inter-layer insulating film formed on the SOI substrate such that the inter-layer insulating film covers the first field-effect transistor and the dummy fill-cell,
wherein the first field-effect transistor has a first gate insulating film formed on the semiconductor layer and a first gate electrode formed on the first gate insulating film,
the dummy fill-cell has a second gate insulating film formed on the semiconductor layer and a second gate electrode formed on the second gate insulating film,
the first gate electrode of the first field-effect transistor is electrically connected to the second gate electrode of the dummy fill-cell via an interconnect formed on the inter-layer insulating film,
a thickness of the second gate insulating film of the dummy fill-cell is larger than that of the first gate insulating film of the first field-effect transistor, and
a gate capacity of the dummy fill-cell is equal to that of the first field-effect transistor.

2. The semiconductor device according to claim 1,
wherein the first gate insulating film of the first field-effect transistor and the second gate insulating film of the dummy fill-cell are each made of silicon oxide or silicon oxynitride.

3. The semiconductor device according to claim 2,
wherein a gate length of the dummy fill-cell is larger than that of the first field-effect transistor.

4. The semiconductor device according to claim 2,
wherein a gate width of the dummy fill-cell is larger than that of the first field-effect transistor.

5. The semiconductor device according to claim 1,
wherein a dielectric constant of the second gate insulating film of the dummy fill-cell is higher than that of the first gate insulating film of the first field-effect transistor.

6. The semiconductor device according to claim 5,
wherein the second gate insulating film of the dummy fill-cell is made of oxide or silicate compound of any one of Hf, Zr, Al, and Ti, and the first gate insulating film of the first field-effect transistor is made of silicon oxide or silicon oxynitride.

7. The semiconductor device according to claim 1, further comprising a second field-effect transistor formed on the semiconductor substrate in a third region different from the first and second regions,
wherein the second field-effect transistor has a third gate insulating film formed on the semiconductor substrate and a third gate electrode formed on the third gate insulating film,
a thickness of the second gate insulating film of the dummy fill-cell is equal to that of the third gate insulating film of the second field-effect transistor, and
the second gate insulating film of the dummy fill-cell and the third gate insulating film of the second field-effect transistor are each made out of a same layer of an insulating film.

8. The semiconductor device according to claim 7,
wherein the first gate insulating film of the first field-effect transistor, the second gate insulating film of the dummy fill-cell, and the third gate insulating film of the second field-effect transistor are each made of silicon oxide or silicon oxynitride.

9. The semiconductor device according to claim 1, further comprising a second field-effect transistor formed on the semiconductor substrate in a third region different from the first and second regions,
wherein the second field-effect transistor has a third gate insulating film formed on the semiconductor substrate and a third gate electrode formed on the third gate insulating film,
a dielectric constant of the second gate insulating film of the dummy fill-cell is higher than that of the first gate insulating film of the first field-effect transistor and that of the third gate insulating film of the second field-effect transistor.

10. The semiconductor device according to claim 9,
wherein the second gate insulating film of the dummy fill-cell is made of oxide or silicate compound of any one of Hf, Zr, Al, and Ti, and the first gate insulating film of the first field-effect transistor and the third gate insulating film of the second field-effect transistor are each made of silicon oxide or silicon oxynitride.

11. The semiconductor device according to claim 9,
wherein a thickness of the third gate insulating film of the second field-effect transistor is larger than that of the first gate insulating film of the first field-effect transistor.

12. A manufacturing method for a semiconductor device by which method a first field-effect transistor is formed in a first region, a dummy fill-cell is formed in a second region different from the first region, and a second field-effect transistor is formed in a third region different from the first and second regions, the manufacturing method comprising the steps of:
(a) preparing an SOI substrate including a semiconductor substrate, an insulating film on the semiconductor substrate, and a semiconductor layer on the insulating film;
(b) eliminating the insulating film and the semiconductor layer in the third region;
(c) following the (b), forming a first gate electrode on the semiconductor layer in the first region via a first gate insulating film, forming a second gate electrode on the semiconductor layer in the second region via a second gate insulating film, and forming a third gate electrode on the semiconductor substrate in the third region via a third gate insulating film;
(d) following the (c), forming an epitaxial layer in contact with an upper surface of the semiconductor layer on both sides of the first gate electrode, an upper surface of the semiconductor layer on both sides of the second gate electrode, and an upper surface of the semiconductor substrate on both sides of the third gate electrode;
(e) following the (d), implanting an impurity into the epitaxial layer on both sides of the first gate electrode and into the semiconductor layer under the epitaxial layer to form a first source/drain, implanting the impurity into the epitaxial layer on both sides of the second gate electrode and into the semiconductor layer under the epitaxial layer to form a second source/drain, and implanting the impurity into the epitaxial layer on both sides of the third gate electrode and into the semiconductor substrate under the epitaxial layer to form a third source/drain;
(f) following the (e), forming an inter-layer insulating film on the semiconductor substrate; and
(g) following the (f), forming a first contact hole reaching the first gate electrode and a second contact hole reaching the second gate electrode in the inter-layer insulating film, and then forming an interconnect electrically connecting the first gate electrode to the second gate electrode via the first contact hole and the second contact hole,
wherein a thickness of the second gate insulating film of the dummy fill-cell is larger than that of the first gate insulating film of the first field-effect transistor, and
a gate capacity of the dummy fill-cell is equal to that of the first field-effect transistor.

13. The manufacturing method for the semiconductor device according to claim 12,
wherein the first gate insulating film of the first field-effect transistor, the second gate insulating film of the dummy fill-cell, and the third gate insulating film of the second field-effect transistor are each made of silicon oxide or silicon oxynitride.

14. The manufacturing method for the semiconductor device according to claim 13,
wherein a gate length of the dummy fill-cell is larger than that of the first field-effect transistor.

15. The manufacturing method for the semiconductor device according to claim 13,
wherein a gate width of the dummy fill-cell is larger than that of the first field-effect transistor.

16. The manufacturing method for the semiconductor device according to claim 12,
wherein a dielectric constant of the second gate insulating film of the dummy fill-cell is higher than that of the first gate insulating film of the first field-effect transistor and that of the third gate insulating film of the second field-effect transistor.

17. The manufacturing method for the semiconductor device according to claim 16,
wherein the second gate insulating film of the dummy fill-cell is made of oxide or silicate compound of any one of Hf, Zr, Al, and Ti, and the first gate insulating film of the first field-effect transistor and the third gate insulating film of the second field-effect transistor are each made of silicon oxide or silicon oxynitride.
